(19) United States
(12) Patent Application Publication
(10) Pub. No.: US 2016/0200974 A1
(43) Pub. Date: Jul. 14, 2016

(54) BRIGHTNESS EQUALIZED QUANTUM DOTS

(71) Applicant: The Board of Trustees of the University of Illinois, Urbana, IL (US)

(72) Inventors: Andrew Smith, Savoy, IL (US); Sung Jun Lim, Urbana, IL (US)

(21) Appl. No.: 14/992,131

(22) Filed: Jan. 11, 2016

Related U.S. Application Data
(60) Provisional application No. 62/102,338, filed on Jan. 12, 2015.

(51) Int. Cl. C09K 11/88; H01L 31/0232; C09K 11/89; G01N 21/64; C30B 19/08; C30B 29/46; C30B 29/48; C30B 29/68; F21V 9/16; C30B 19/12

(52) U.S. Cl. CPC C09K 11/883; F21V 9/16; H01L 31/02322; C09K 11/892; C30B 19/12; C30B 19/08; C30B 29/46; C30B 29/48; C30B 29/68; G01N 21/645; G01N 2201/067

(57) ABSTRACT

The present invention relates to brightness equalized quantum dots (QDs). These quantum dots are semiconductor nanocrystals having tunable fluorescence brightness across a broad range of emission colors and excitation wavelengths, enabling equalization of the light output of an array of these dots. This tunability and equalization is achieved by the chemical and structural design of the nanocrystals to obtain a predefined emission wavelength, extinction coefficient, and quantum yield for a given excitation input. These quantum dots provide improved performance for a variety of optical applications, including, e.g., fluorescence probes, solar panels, displays, and computational devices.

### RELATED APPLICATION

This application claims priority to U.S. Provisional Patent Application Ser. No. 62/102,338 filed on Jan. 12, 2015, the disclosure of which is incorporated by reference herein in its entirety.

### FEDERAL FUNDING LEGEND

This invention was made with government support under Grant No. R00CA153914 awarded by National Institutes of Health. The government has certain rights in the invention.

### FIELD OF THE INVENTION

The present invention relates to brightness equalized quantum dots (QDs). These quantum dots are semiconductor nanocrystals having tunable fluorescence brightness across a broad range of emission colors and excitation wavelengths, enabling equalization of the light output of an array of these dots. This tunability and equalization is achieved by the chemical and structural design of the nanocrystals to obtain a predefined emission wavelength, extinction coefficient, and quantum yield for a given excitation input. These quantum dots provide improved performance for a variety of optical applications, including, e.g., fluorescence probes, solar panels, displays, and computational devices.

### BACKGROUND OF THE INVENTION

Quantum dots are semiconductor nanocrystals that display quantum size effects. The electronic properties of quantum dots are between those of bulk semiconductors and those of discrete molecules of comparable size. Quantum dots have optoelectronic properties such as band gap, which, for a given composition, can be tuned as a function of particle size and shape. This means that their electronic properties depend on their dimensions, presenting an opportunity to optimize their size and shape for light absorption and photocurrent production. This tunability makes them useful for many different applications in optical, chemical, and electronic fields.

As molecular labels for cells and tissues, fluorescent probes have shaped our understanding of biological structures and processes. However their capacity for quantitative analysis is limited because photon emission rates from multicolor fluorophores are dissimilar, unstable, and often unpredictable, which obscures correlations between measured fluorescence and molecular concentration. Here we introduce a new class of light-emitting quantum dots with tunable and equalized fluorescence brightness across a broad range of colors. The key feature is independent tunability of emission wavelength, extinction coefficient, and quantum yield through distinct structural domains in the nanocrystal. Precise tuning eliminates a 100-fold red-to-green brightness mismatch of size-tuned quantum dots at the ensemble and single-particle levels, which substantially improves quantitative imaging accuracy in biological tissue. We anticipate that these materials engineering principles will vastly expand the optical engineering landscape of fluorescent probes, facilitate quantitative multicolor imaging in living tissue, and improve color tuning in light-emitting devices.

Semiconductor quantum dots (QDs) are the subject of a diverse range of fundamental and applied research efforts in biomedical imaging, light-emitting devices, solar cells, and quantum computing. See (1) Kovalenko et al., (2) Kairdolf et al., (3) Anikeeva et al., (4) Salter et al., (5) Talapin et al., (6) Lee et al., (7) Konstantatos et al., (8) Nozik et al., (9) Ladd et al., (10) Garcia-Santamaria et al., (11) Tisdale et al., and (12) Vu et al. These light-absorbing, light-emitting nanocrystals provide numerous optical and electronic properties that are not available from other materials. In particular for molecular and cellular imaging applications, QDs have a unique combination of bright and stable fluorescent light emission, widely tunable and pure emission colors, and broadband excitation. In recent years, these properties have provided a means to image and track proteins and nucleic acids at the single-molecule level for long durations and to multiplex the detection of a large number of molecules and biomolecular processes simultaneously without crosstalk. See (13) Cutler et al., (14) Kobayashi et al., and (15) Zrahesyskiy et al. The critical capacity to tune the emission color of a QD derives from the quantum confinement effect, whereby the nanocrystal dimensions (size and shape) dictate the energies of excited-state charge carriers (electrons and holes). See (16) Ekimov et al., (17) Brus et al., (18) Smith et al., and (19) Yu et al. Reducing the nanocrystal size confines the charge carriers to a smaller region in space, which increases their energies, widens the electronic bandgap, and shifts the absorption and emission spectra to higher energy (shorter wavelength). Through synthetic advances over the last two decades, size-tunable QDs can now be readily prepared from a variety of materials, which has yielded emitters throughout the near-ultraviolet, visible, near-infrared, and mid-infrared spectra with fluorescence quantum yields approaching 100%. See (20) Murray et al., (21) Xie et al., (22) Murray et al., (23) Yu et al., (24) McBride et al., and (25) Keuleyan et al.

An undesirable consequence of exploiting the quantum confinement effect for spectral tuning is that different colors of emitters are necessarily dissimilar in fluorescence brightness. This is primarily due to differences in extinction coefficients (ε): the size determines the number of constituent atoms and bonds, which are the fundamental units of collective electronic oscillation mediating light absorption and extinction. More atoms per particle provide more bonding electrons, which leads to higher oscillator strengths and higher light collecting efficiency per particle. See (26) Leatherdale et al. and (27) Smith et al. Thus for a spherical nanocrystal with radius r, ε scales approximately with volume (ε∝r³) in single-photon excitation mode.

Light absorption results in an excited state electron that then decays to its ground states by converting its energy to fluorescent light; the efficiency of this process is the quantum yield (QY). Thus the relative fluorescence brightness, Bᵣₑₗ, is simply the product: See Equation 1. See (28) Wurth et al.

Bᵣₑₗ=ε·QY Equation 1.

If QY is similar for each quantum dot color, the brightness can differ by orders of magnitude across a small spectral range simply because the extinction coefficient is intrinsically coupled to the size and thus the emission wavelength (λₑₘ).

It is seen from the foregoing that there are limitations in the use of quantum dots because of the difficulty of obtaining equalized brightness across a broad range of emission wavelengths, i.e. colors for visible wavelengths, and across a broad range of excitation wavelengths. It is apparent there is an ongoing need for tunable, brightness-equalized quantum dots. These quantum dots would provide improved performance for a variety of optical applications, including, e.g., fluorescence probes, solar panels, displays, and computational devices.

### BRIEF DESCRIPTION OF THE FIGURES

FIGS. 1A to 1F provide comparisons between different types of quantum dots (QDs).

FIGS. 1A to 1C are directed to conventional size-tuned quantum dots (QDs) and FIGS. 1D to 1F are directed to brightness-equalized QDs. FIG. 1A—Schematic depictions of ST-QD structures show that emission wavelength and extinction coefficient are largely dictated by the CdSe core size, and that the shell, composed of CdS, ZnS or alloys of the two, controls the quantum yield. FIG. 1B—Extinction coefficient spectra of ST-QDs show a wide disparity in light absorption per-particle, resulting in as shown in FIG. 1C, dissimilar fluorescence brightness values when excited at the same wavelength (here 400 nm). FIG. 1D—Schematic depiction of BE-QD structures for which the core size is fixed and wavelength is tuned through the bandgap of composition-tunable alloys. The shell comprises two spherically concentric domains: the CdS shell is used to precisely match the extinction coefficients and the ZnS shell is used to equalize the quantum yields. FIG. 1E—Extinction coefficient spectra of BE-QDs show convergence below 450 nm, resulting as shown in FIG. 1F, equalized fluorescence brightness when excited at the same wavelength (400 nm). Graphs depict representative experimental data plotted with wavelength axes scaled in proportion to energy.

FIG. 2A to 2C: Extinction coefficient spectra of nanocrystalline materials used for cores and shells in the quantum dot work as described herein. Spectra are shown for CdSe QDs with different sizes (FIG. 2A), HgₓCd₁₋ₓSe_{y}Si_{1-y} QDs with fixed size (2.3 nm) and different compositions (x,y) (FIG. 2B), and CdS QDs with different core sizes (FIG. 2C). Insets show absorption coefficients at specific wavelengths.

FIGS. 3A to 3J. QD extinction coefficient equalization through CdS shell growth. FIGS. 3A, 3B, 3E, 3F, and 3I depict a representative equalization process for two CdSe cores with different sizes (2 nm and 4 nm) and FIGS. 3C, 3D, 3G, 3H, and 3J depict a representative equalization process for two alloy cores (HgₓCd₁₋ₓSe_{y}Si_{1-y}) with different compositions but similar sizes. FIGS. 3A to 3D—Extinction coefficient spectra are depicted for the 4 cores during capping with CdS in deposition increments of 0.8 monolayers; extinction increases with increasing shell thickness. Spectra depict the first 5-7 increments. FIG. 3E and FIG. 3G show the trends in extinction coefficient values at 400 nm with different CdS shell thicknesses. Dashed lines are extinction isolines, connection points of equal extinction. FIGS. 3F and 3H show spectra of two colors of QDs with matched extinction, showing strong correlation between 350-450 nm. Insets show ratios of spectra each of these extinction-matched pairs. FIGS. 3I and 3J) show the wavelength tunability of the resulting QDs, with substantially wider spectral range provided with alloy cores. Four example QD colors are shown in FIG. 3J.

FIGS. 4A to 4F relate to quantum yield and brightness equalization. FIGS. 4A, 4C, and 4E depict representative data for QDs based on size-tuned CdSe cores. FIGS. 4B, 4D, and 4F depict representative data for composition-tuned cores. FIGS. 4A and 4B—Quantum yield values measured for QDs capped with different CdS shell thicknesses in organic solvents. The x-axis is the extinction coefficient at 400 nm during shell growth and the y-axis is QY excitation at 400 nm. FIGS. 4C and 4D—relative brightness measured for QDs capped with CdS and then ZnS shells with different ZnS shell thicknesses, with 400 nm excitation. FIGS. 4E and 4F—Relative brightness determined for different excitation wavelengths for two QD colors in aqueous solution. Insets show wavelength-dependent ratios of brightness.

FIGS. 5A to 5D relate to brightness comparisons of ST-QDs and BE-QDs at the ensemble level and the single-particle level. FIG. 5A—Measured fluorescence spectra and integrated brightness of two colors of conventional ST-QDs with 400 nm excitation. FIG. 5B—Histogrammed single-particle (SP) brightness values of individual QDs measured using epifluorescence microscopy (images at right show example micrographs). FIG. 5C—Measured fluorescence spectra and integrated brightness values of two colors of BE-QDs upon excitation at 400 nm. FIG. 5D—Histogrammed brightness values of individual QDs measured using epifluorescence microscopy. Each fluorescence image has a square edge length of 14 μm. FIGS. 6A to 6E depict brightness comparisons of ST-QDs and BE-QDs with two-photon excitation. FIG. 6A—Measured brightness of three colors of conventional ST-QDs upon excitation at wavelengths between 700-1000 nm. Inset shows fluorescence intensity (arbitrary units) vs. excitation power (mW) plots for each QD with 780 nm excitation, with indicated log-log plot slopes (m). FIG. 6B—Measured fluorescence brightness of three colors of BE-QDs upon excitation between 700-1000 nm. Inset shows intensity-power plots. FIGS. 6C and 6D—Intravital multiphoton fluorescence images of a mouse mammary tumor showing fluorescence in blood vessels after intravenous injection of a mixture of green and red QDs in a 1:1 molar ratio. ST-QDs were injected into the mouse in panel (c), n=3, and BE-QDs were injected into the mouse in panel (FIG. 6D), n=3. Scale bar, 50 μm. Tumor cells expressing a fluorescent protein (CFP) provide contrast for interstitial tissue. FIG. 6E—Measured brightness values of the red and green channels were divided for each in vivo experiment and plotted next to the corresponding ratio for in vitro values. Error bars denote standard error of measured brightness.

FIG. 7A shows the difference between the QY calculated by using the ratio of Aₓ/A_{Ref} and that calculated by using fₓ/f_{Ref}. Notice that there can be up to 10% error in QY from absorbances even when both A_{Ref} and Aₓ are lower than 0.1 but the values are different (e.g. A_{Ref}=0.01 and Aₓ=0.1). Moreover, such deviation quickly becomes enormous when the absorbance of a sample further increases relative to the absorbance of the reference. This is generally the case for calculating an excitation wavelength-dependent QY of a QD sample from its PLE spectrum. FIG. 7B shows that for a dilute QD solution with an absorbance <0.1 near the bandedge, the solution can still show very high absorbance as the wavelengths gets shorter due to the band-type electronic structure of a QD.

### SUMMARY OF THE INVENTION

The present invention relates to brightness equalized quantum dots (QDs). These quantum dots are semiconductor nanocrystals having tunable fluorescence brightness across a broad range of emission colors and excitation wavelengths, enabling equalization of the light output of an array of these dots. This tunability and equalization is achieved by the chemical and structural design of the nanocrystals to obtain a predefined emission wavelength, extinction coefficient, and quantum yield for a given excitation input. These quantum dots provide improved performance for a variety of optical applications, including, e.g., fluorescence probes, solar panels, displays, and computational devices.

### DETAILED DESCRIPTION OF THE INVENTION

The present invention relates to an array of two or more semiconductor nanocrystals in which the fluorescence brightness is matched to a predefined brightness, the nanocrystals comprising: (a) an alloy core selected from a ternary or higher order alloy core that controls emission color by the selection of the composition of the core or a binary alloy core that controls emission color by the selection of the core diameter, said emissions for said at least two or more nanocrystals being of at least two different emission wavelengths; (b) a first epitaxially deposited concentric shell of controlled thickness, deposited on the alloy core, that modulates the extinction coefficient of the emission of the alloy core to match the extinction coefficients of the alloy cores across the array of nanocrystals; and (c) a second epitaxially deposited concentric shell of controlled thickness, deposited on the first concentric shell to match the quantum yield of the emission of the alloy cores across the array of nanocrystals.

In another aspect the present invention relates to an array wherein the fluorescence brightness is matched across a range of emission colors and excitation wavelengths

In another aspect the present invention relates to a nanocrystal, wherein the alloy core is a ternary or higher order alloy core that controls emission color by the selection of the composition of the core.

In another aspect the present invention relates to a nanocrystal, wherein the ternary or higher order alloy core comprises an alloy selected from a mixture of at least three of the following elements: cadmium, mercury, selenium, sulfur, tellurium, and zinc.

In another aspect the present invention relates to a nanocrystal, wherein the alloy core is a ternary alloy core that controls emission color by the selection of the composition of the core.

In another aspect the present invention relates to a nanocrystal, wherein the ternary alloy core comprises a mixture of (a) a mixture of cadmium, selenium, and sulfur or (b) a mixture of mercury, selenium, and sulfur.

In another aspect the present invention relates to a nanocrystal, wherein the alloy core is a binary alloy core that controls emission color by the selection of the core diameter.

In another aspect the present invention relates to a nanocrystal, wherein the higher order alloy core is a quaternary alloy core that controls emission color by the selection of the composition of the core.

In another aspect the present invention relates to a nanocrystal, wherein the alloy core comprises Hg(x)Cd(1-x)Se(y)S(1-y) wherein x and y are independently selected from any real number between zero and 1, inclusive, i.e. including zero and 1.

In another aspect the present invention relates to a nanocrystal, wherein the alloy core comprises Cd(x)Zn(1-x)Se(y)S(1-y) wherein x and y are independently selected from any real number between zero and 1, inclusive, i.e. including zero and 1.

In another aspect the present invention relates to a nanocrystal, wherein the first shell comprises CdS.

In another aspect the present invention relates to a nanocrystal, wherein the second shell comprises ZnS.

In another aspect the present invention relates to a nanocrystal, having a diameter from about 2 nm to about 100 nm.

In another aspect the present invention relates to a nanocrystal, wherein the alloy core has a diameter from about 2 nm to about 20 nm.

In another aspect the present invention relates to a nanocrystal, wherein the alloy core has a diameter from about 2 nm to about 10 nm.

In another aspect the present invention relates to a nanocrystal, wherein the alloy core has a diameter from about 2 nm to about 5 nm.

In another aspect the present invention relates to a nanocrystal, wherein the first shell has a thickness from about 0.1 nm to about 10 nm.

In another aspect the present invention relates to a nanocrystal, wherein the first shell has a thickness from about 5 nm to about 10 nm.

In another aspect the present invention relates to a nanocrystal, wherein the first shell has a thickness from about 0.3 nm to about 5 nm.

In another aspect the present invention relates to a nanocrystal, wherein the second shell has a thickness from about 0.1 nm to about 10 nm.

In another aspect the present invention relates to a nanocrystal, wherein the second shell has a thickness from about 0.1 nm to about 5 nm.

In another aspect the present invention relates to a nanocrystal, wherein the second shell has a thickness from about 0.1 nm to about 3 nm.

In another aspect the present invention relates to a biomedical imaging device comprising an array of 2 or more nanocrystals.

In another aspect the present invention relates to a biomedical imaging device that is a multiplex biomedical imaging device.

In another aspect the present invention relates to a fluorescent lighting device comprising an array of 2 or more nanocrystals.

In another aspect the present invention relates to a biological or biomedical fluorescent probe comprising an array of 2 or more nanocrystals.

In another aspect the present invention relates to a biomedical probe that is a diagnostic probe.

In another aspect the present invention relates to a solar panel comprising an array of 2 or more nanocrystals.

In another aspect the present invention relates to an optoelectronic device comprising an array of 2 or more nanocrystals.

In another aspect the present invention relates to an optoelectonic device selected from displays, lasers, and sensors.

In another aspect the present invention relates to a computational device comprising an array of 2 or more nanocrystals.

In another aspect the present invention relates to a computational device selected from a device for optical data storage, optical data transfer, or optical calculations.

In another aspect the present invention relates to a method for making a semiconductor nanocrystal in which one or more of the following properties of the nanocrystal is matched to a predefined value: (i) extinction coefficient, (ii) absorption cross section, (iii) fluorescence quantum yield, or (iv) fluorescence brightness; comprising:

(a) preparing an alloy core selected from a ternary or higher order alloy core that controls emission color by the selection of the composition of the core or a binary alloy core that controls emission color by the selection of the core diameter;
(b) epitaxially depositing a first concentric shell of controlled thickness on the alloy core, that modulates the extinction coefficient of the emission of the alloy core to match the extinction coefficient to a predefined value; and
(c) epitaxially depositing a second concentric shell of controlled thickness on the first concentric shell to match the quantum yield of the emission of the alloy core to a predefined value; wherein the resulting nanocrystal exhibits one or more properties of the predefined value.

In another aspect the present invention relates to a method for making a semiconductor nanocrystal wherein the property of the nanocrystal is fluorescence brightness and the fluorescence brightness is matched to a predefined value across a range of emission colors and excitation wavelengths.

In another aspect the present invention relates to a method for making two or more semiconductor nanocrystals having different compositions, wherein the selected property of each nanocrystal is matched to a predefined value.

In another aspect the present invention relates to a method for making a semiconductor nanocrystal wherein the alloy core is a ternary or higher order alloy core that controls emission color by the selection of the composition of the core.

In another aspect the present invention relates to a method for making a semiconductor nanocrystal wherein the alloy core is a binary alloy core that controls emission color by the selection of the core diameter.

In another aspect the present invention relates to a method for equalizing the fluorescence brightness of an array of two or more semiconductor nanocrystals to a predefined brightness, comprising:
(I) selecting one or more semiconductor nanocrystals of a first nanocrystal composition, comprising:
   (a) an alloy core selected from a ternary or higher order alloy core that controls emission color by the selection of the composition of the core or a binary alloy core that controls emission color by the selection of the core diameter, said emission colors for said at least two or more nanocrystals being of at least two different emission wavelengths;
   (b) a first epitaxially deposited concentric shell of controlled thickness, deposited on the alloy core, that modulates the extinction coefficient of the emission of the alloy core to match the extinction coefficients across the array of nanocrystals; and
   (c) a second epitaxially deposited concentric shell of controlled thickness, deposited on the first concentric shell to match the quantum yield of the emission of the alloy core across the array of nanocrystals;
(II) selecting one or more semiconductor nanocrystals of a second nanocrystal composition, comprising:
   (a) an alloy core selected from a ternary or higher order alloy core that controls emission color by the selection of the composition or a binary alloy core that controls emission color by the selection of the core diameter, said emission colors for said at least two or more nanocrystals being of at least two different emission wavelengths;
   (b) a first epitaxially deposited concentric shell of controlled thickness, deposited on the alloy core, that modulates the extinction coefficient of the emission of the alloy core to match the extinction coefficients of the alloy core across the array of nanocrystals; and
   (c) a second epitaxially deposited concentric shell of controlled thickness, deposited on the first concentric shell to match the quantum yield of the emission of the alloy core across the array of nanocrystals; and
(III) optionally selecting one or more semiconductor nanocrystals from one or more further nanocrystal compositions having a composition other than the first or second nanocrystal composition, comprising:
   (a) an alloy core selected from a ternary or higher order alloy core that controls emission color by the selection of the composition or a binary alloy core that controls emission color by the selection of the core diameter, said emission colors for said at least two or more nanocrystals being of at least two different emission wavelengths;
   (b) a first epitaxially deposited concentric shell of controlled thickness, deposited on the alloy core, that modulates the extinction coefficient of the emission of the alloy core to match the extinction coefficients across the array of nanocrystals; and
   (c) a second epitaxially deposited concentric shell of controlled thickness, deposited on the first concentric shell to match the quantum yield of the emission of the alloy core across the array of nanocrystals;
      wherein the composition of the first, second, and any optional further nanocrystal composition is modified such that the fluorescence brightness of the array is equalized to the predefined brightness.

In another aspect the present invention relates to a method for equalizing the fluorescence brightness of an array of two or more semiconductor nanocrystals to a predefined brightness, wherein the fluorescence brightness of the array is matched across a range of emission colors and excitation wavelengths.

In another aspect the present invention relates to a method for equalizing the fluorescence brightness of an array of two or more semiconductor nanocrystals to a predefined brightness, wherein the alloy core in I(a), II(a), and III(a) is a ternary or higher order alloy core that controls emission color by the selection of the composition of the core.

In another aspect the present invention relates to a method for equalizing the fluorescence brightness of an array of two or more semiconductor nanocrystals to a predefined brightness, wherein the alloy core in I(a), II(a), and III(a) is a binary alloy core that controls emission color by the selection of the core diameter.

In another aspect the present invention relates to a method for equalizing the fluorescence brightness of an array of two or more semiconductor nanocrystals to a predefined brightness, wherein the alloy core of the first nanocrystal compositions, the alloy core of the second nanocrystal compositions, and the alloy core of any further nanocrystal compositions are selected such that the first, second and any further alloy nanocrystal compositions are all the same.

In another aspect the present invention relates to a method for equalizing the fluorescence brightness of an array of two or more semiconductor nanocrystals to a predefined brightness, wherein the alloy core of the first nanocrystal compositions, the alloy core of the second nanocrystal compositions, and the alloy core of any further nanocrystal compositions are selected such that the first, second and any further alloy nanocrystal compositions are each different from each other.

In another aspect the present invention relates to a method for equalizing the fluorescence brightness of an array of two or more semiconductor nanocrystals to a predefined brightness, wherein the alloy core of the first nanocrystal compositions, the alloy core of the second nanocrystal compositions, and the alloy core of any further nanocrystal compositions are selected such that at least one of the following pairs of nanocrystal alloy compositions are different: the first and second alloy nanocrystal compositions, the first and any further alloy nanocrystal compositions, or the second and any further alloy nanocrystal compositions.

### DEFINITIONS

As used herein, the following terms have the indicated meanings unless expressly stated to the contrary:

The term “brightness” as used herein refers to the amount of light output, i.e. fluorescence, emitted by a source such as a quantum dot.

The term “brightness matched” as used herein means that the amount of light output, i.e. fluorescence is equal, or substantially equal from two or more emitting sources such as emitting quantum dots. Substantially equal means that the brightness of the sources is matched to within 20%, preferably 10%, more preferably 5% and even more preferably 1% to a target brightness or to each other.

The term “extinction coefficient” as used herein is used in its ordinary sense as a measure of how strongly a substance attenuates light at a given wavelength. It is generally represented by the symbol ε. Alternatively, the “absorption cross section” is another similar measure to extinction coefficient.

The term quantum efficiency, as used herein, is the ratio of light energy absorbed to light emitted, i.e. fluorescence. The quantum efficiency is a measure of how much absorbed light energy is converted to fluorescence.

The terms “QD” and “QDs) as used herein are abbreviations, respectively for “quantum dot” and “quantum dots”.

The term “QY” is an abbreviation for “quantum yield”, which with respect to a radiation-induced process is the number of times a specific event occurs per photon absorbed by the system, in this case a quantum dot.

Brightness Equalized Quantum Dots and Arrays

In the present invention we have demonstrated the ability to precisely tune the rate of photon absorption and photon emission of colloidal semiconductor quantum dots to balance their multicolor optical disparities. We created multicolor particles with nearly identical fluorescence brightness when excited at a wide range of excitation wavelengths (350-450 nm) that are compact in overall dimensions that can serve as next-generation emitters for quantitative imaging applications at the single-molecule level and in living systems. We project that these materials will be especially important for imaging in complex tissues where quantitative molecular imaging capabilities are significantly lacking, yielding a consistent and tunable number of photons per tagged biomolecule, for precise color matching in light emitting devices and displays, and for photon-on-demand encryption applications. The same principles should be applicable to a wide variety of other materials for further expansion of the spectral range, including widely varying crystal structures such as PbS and PbSe materials, Group materials, and other alloys.

It is known, that the photoluininescence of a quantum dot can be manipulated to specific wavelengths by controlling particle diameter. For example, quantum dots of smaller radius (such as a radius of 2-3 nm) emit shorter wavelengths resulting in colors such as blue and green, whereas quantum dots of larger radius (such as 5-6 nm) emit longer wavelengths such as red or orange.

As discussed above, an undesirable consequence of exploiting the quantum confinement effect for spectral tuning is that different colors of emitters are necessarily dissimilar in fluorescence brightness. This is primarily due to differences in extinction coefficients (ε): the size determines the number of constituent atoms and bonds, which are the fundamental units of collective electronic oscillation mediating light absorption and extinction. More atoms per particle provide more bonding electrons, which leads to higher oscillator strengths and higher light collecting efficiency per particle. See (26) Leatherdale et al. and (27) Smith et al. Thus for a spherical nanocrystal with radius r, ε scales approximately with volume (ε∝r³) in single-photon excitation mode. Light absorption results in an excited state electron that then decays to its ground states by converting its energy to fluorescent light; the efficiency of this process is the quantum yield (QY). Thus the relative fluorescence brightness, Bᵣₑₗ, is simply the product. See Equation 1. See (28) Wurth et al.

Bᵣₑₗ=ε·QY Equation 1.

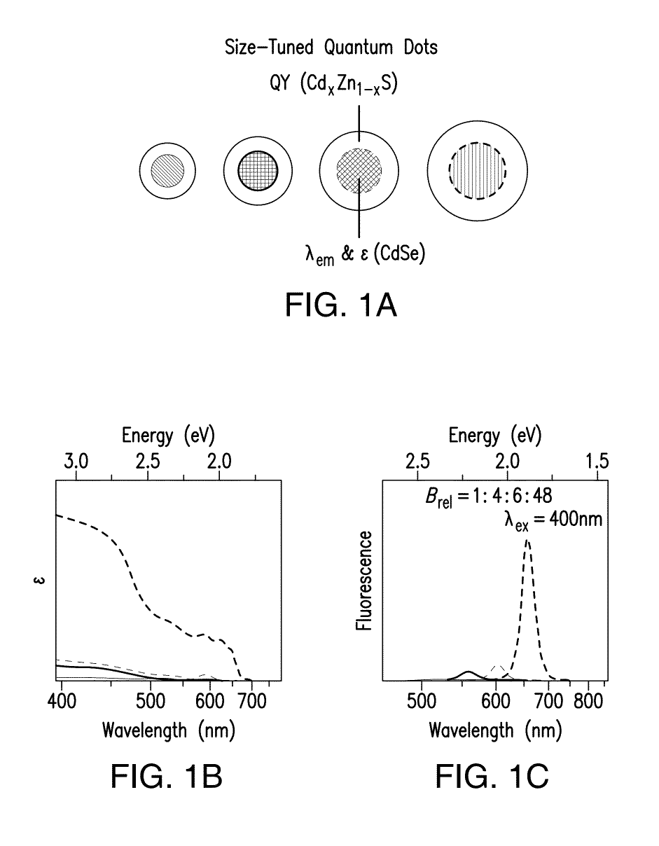

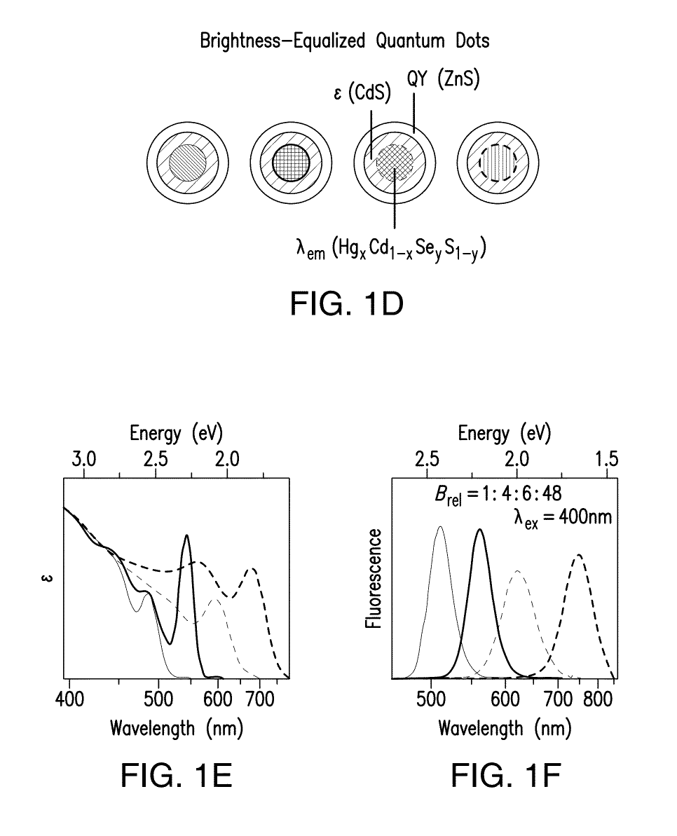

If QY is similar for each quantum dot color, the brightness can differ by orders of magnitude across a small spectral range simply because the extinction coefficient is intrinsically coupled to the size and thus the emission wavelength (λₑₘ). This effect is demonstrated in FIGS. 1A, 1B, and 1C. Prototypical size-tuned quantum dots (ST-QDs) (depicted in FIG. 1A) are composed of CdSe cores with a size that largely determines λₑₘ and ε. The core is coated with a shell composed of CdS, ZnS, or their alloys, which provides electronic insulation and almost entirely dictates QY, but can also contribute significantly to λₑₘ and ε. As shown in FIG. 1B, four sizes of ST-QDs thus have very dissimilar extinction coefficients that increase with size; therefore upon excitation by short-wavelength light (e.g. 400 nm), redder quantum dots have greater brightness compared to bluer quantum dots. As shown in FIG. 1C, QDs emitting at 650 nm have a ˜48-fold greater fluorescence brightness compared with 520 nm QDs based on extinction coefficient alone. See (29) Arnspang ety al. Dissimilarities in QY tend to further exacerbate this effect (vide infra). In two-photon excitation mode the mismatch in relative brightness is even wider, on the order of 100-200-fold from green to red, as ε scales proportionally with r⁴. See (30) Pu et al. Two-photon excitation is critically important for bioimaging because long-wavelength illumination intrinsic to the modality both enhances depth penetration through thick tissue and reduces tissue damage. See (31) Wyckoff et al., (32) Entenberg et al., and (33) Larson et al. The color-dependent optical mismatch of quantum dots is even more pronounced in biological media, as small quantum dots with the lowest fluorescence intensity overlap the most with blue/green autofluorescence of biological molecules, reducing their detection threshold as they are buried in a noisy background and shoulders of spectrally adjacent red emitters that are much brighter. See (34) Gao et al., and (35) Zhou ε t al. The consequence of this mismatch is that the multiplexing advantages of quantum dots are substantially diminished when detecting, imaging, and tracking biomolecular analytes, and only a limited optical spectrum is regularly utilized.

Here we describe the development of brightness-equalized quantum dots (BE-QDs) with matched fluorescence brightness across a broad spectrum of colors in the visible and near-infrared. The general concept is to decouple the three key optical parameters, λₑₘ, ε, and QY, to the greatest extent possible by allowing them to derive from independent structural domains in the nanocrystal. FIG. 1D depicts the 3-domain core/shell/shell BE-QD structure. We replace conventional CdSe binary cores that have a fixed bulk bandgap (1.76 eV) with ternary CdSe_{y}Si_{1-y} or HgₓCd₁₋ₓSe alloys or quaternary HgₓCd₁₋ₓSe_{y}Si_{1-y} alloys that have continuously tunable bulk bandgaps from 0 eV to 2.5 eV. This allows us to adjust the bandgap, and thus emission wavelength, without changing the nanocrystal size. Because these size-matched cores have a similar number of atoms, the extinction coefficients are intrinsically similar and can be matched precisely across a broad range of excitation spectra by epitaxial growth of a strongly absorbing shell material (CdS) using efficient deposition processes. In a final step, the overgrowth of a wide-bandgap ZnS shell normalizes the QY values even after transfer to oxidizing conditions in aqueous solution, with little impact on extinction. As a result, λₑₘ, ε, and QY are decoupled and can be independently adjusted to vastly expand the optical properties of quantum dot emitters, yielding a degree of parametric tunability that is currently not available from any other type of material. We demonstrate that this leads to normalization of brightness for quantum dots emitting across a wide wavelength range from 500-800 nm with excitation between 350-450 nm. Brightness equalization is observed at both the ensemble level and the single-molecule level as well as under two-photon excitation conditions, which we show translates to improved quantitative imaging capabilities in complex biological tissue

Matching Extinction Coefficients

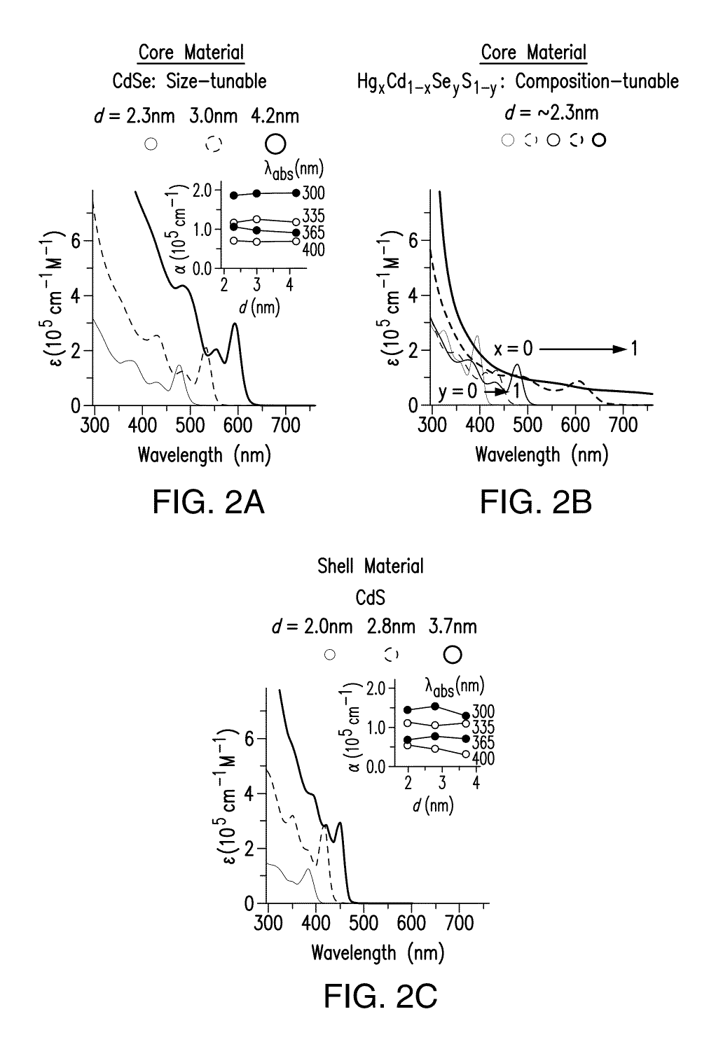

To match ε between different QD colors, we first measured the wavelength-dependent ε values for individual materials used in the different structural domains of ST-QD and BE-QD. FIG. 2 depicts ε-spectra for three nanocrystalline materials: size-tunable core materials (CdSe), composition-tunable core materials (HgₓCd₁₋ₓSe_{y}Si_{1-y}), and shell material used for extinction matching (CdS). CdS, CdSe, and CdSe_{y}Si_{1-y} were prepared by reproducible non-injection heat-up methods and HgₓCd₁₋ₓSe(S) was synthesized from a pre-formed CdSe(S) core with Hg added through cation exchange in a controllable second step. Composition and values of ε were measured through a combination of absorption spectrophotometry, transmission electron microscopy (TEM), and inductively coupled plasma optical emission spectrometry (ICP-OES), as described in the Methods section. FIG. 2A shows ε-spectra for three sizes of binary CdSe nanocrystals; absorption spectra redshift with increasing diameter, asymptotically approaching the bulk CdSe bandgap (E_{g}=1.76 eV or 730 nm). Emission spectra (not shown) are close in wavelength to the longest wavelength peak in these spectra. The depicted ˜100-nm redshift is accompanied by a ˜5-6-fold increase in ε at short wavelengths (300-400 nm). FIG. 2B depicts the result when the size is fixed and the wavelength is tuned by composition. Two important effects are clear: the tunable range is very wide (here 400-800 nm) and the extinction coefficients between different colors are closer (1- to 2-fold, depending on the specific colors considered). FIG. 2C shows ε-spectra for nanocrystals composed of the binary shell material CdS, yielding similar size-tunable attributes as the CdSe core but with a substantial blueshift due to the larger bulk CdS bandgap (E_{g}=2.5 eV or 520 nm). Importantly, while there is a large dissimilarity in ε between different CdS and CdSe sizes, the absorption coefficient, a (shown in the insets), is fairly constant with size. The parameter a provides a measure of the light-absorption capacity per atom or equivalently per unit cell in the crystal. See Equation 2.

$$α = \frac{1000 \cdot ln ( 10 )}{{N}_{A}} \cdot ɛ \cdot {( \frac{4}{3} π {r}^{3} )}^{- 1} . \qquad Equation 2$$

The independence of absorption cross section at high energy (300-400 nm) for quantum dots is a well-known attribute of quantum confinement, which mostly affects band-edge energy levels. See (26) Leatherdale et al., (36) Klimov et al., and (37) Jasieniak et al. This a data provided in the inset thus provides a metric for the quantity of extinction per atom of Cd/S deposited as shell material, and predicts a linear increase in extinction coefficient in the low-wavelength spectral range with increasing shell volume.

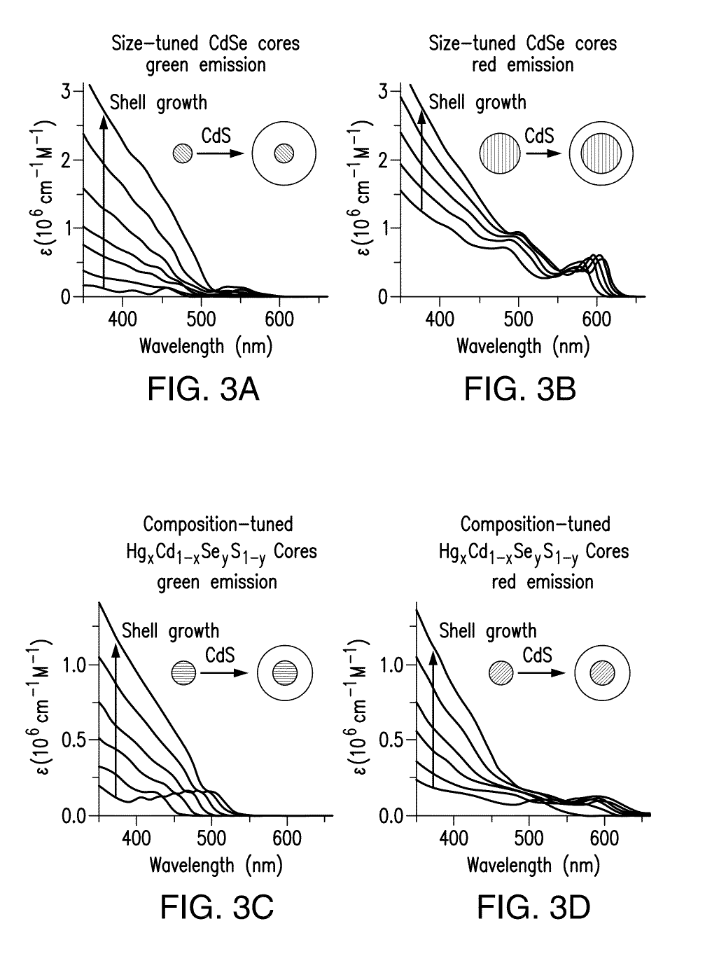

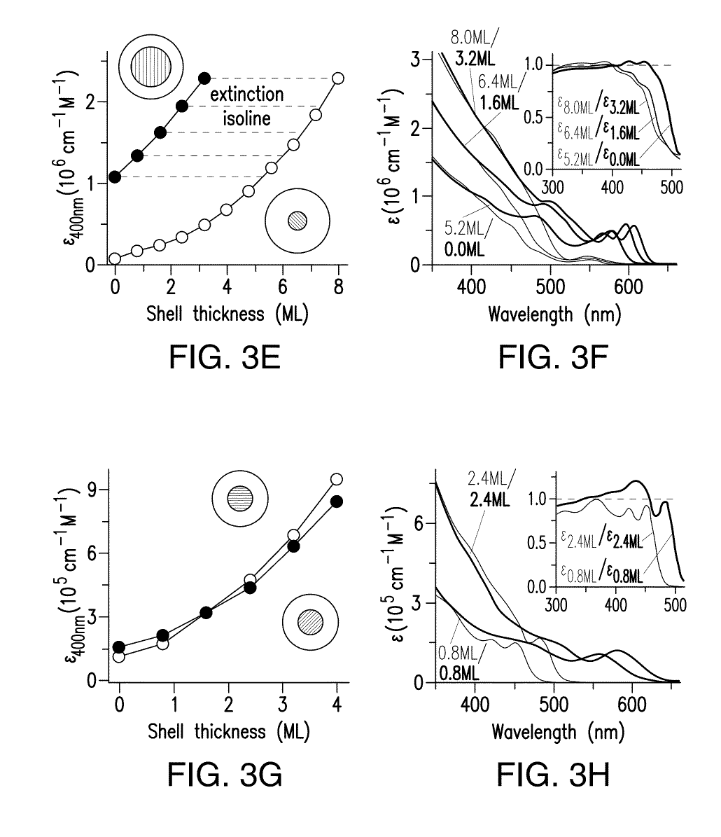

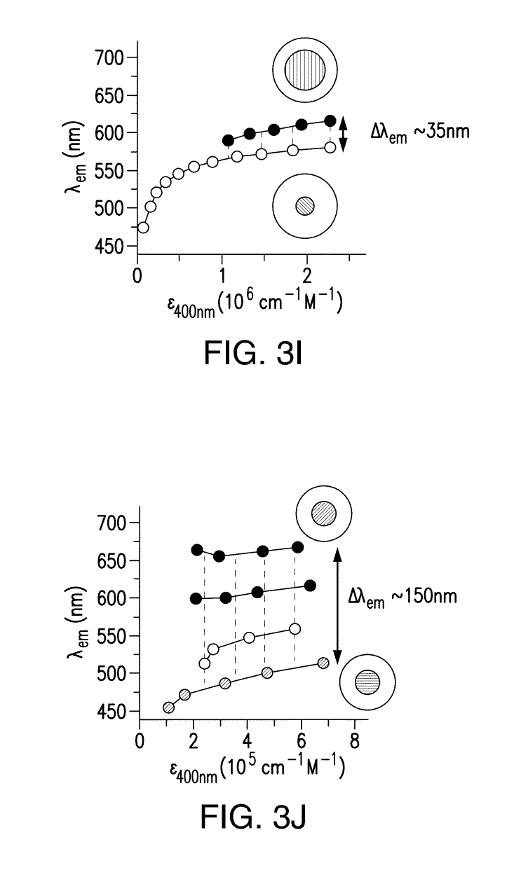

We are most interested in equalizing quantum dot extinction coefficients in the 350-450 nm spectral range, a window allowing excitation of a broad range of colors in the visible and near-infrared, and corresponding to the 700-900 nm two-photon band commonly employed with standard femtosecond laser systems. To do so, we epitaxially deposited CdS shells on pre-formed cores, with the expectations that (1) the CdS domain will provide a predictable and continuously tunable quantity of ε per particle and (2) the wide bandgap CdS shell will increase QY through electronic insulation. We discuss the impact on ε first. Shells were grown homogeneously, layer-by-layer, in increments of 0.8 lattice monolayers (ML), using highly reactive cadmium oleate and bis(trimethylsilyl)sulfide precursors to ensure quantitative deposition without introducing new CdS nuclei, as confirmed by TEM. FIG. 3 shows the effects on ε, comparing the results when either using two colors of size-tuned cores (left columns: CdSe diameters of 2.0 nm or 4.3 nm), or when using two colors of composition-tuned cores (right columns: HgₓCd₁₋ₓSe_{y}Si_{1-y}) with the same size. For all core materials, CdS deposition substantially increased ε at wavelengths shorter than 500 nm (see FIGS. 3A-D). FIGS. 3E and 3G summarize the trends for ε at 400 nm, highlighting extinction isolines (dotted lines) that connect different quantum dot colors with specific shell thicknesses at which the two ε values match. Whereas the quantum dots generated from size-tuned CdSe cores require very different quantities of shell deposition for matching different quantum dot colors, ternary alloy cores initially have similar extinction coefficients, so the extinction matching process is greatly simplified, as extinction values at 400 nm nearly matched throughout the CdS shell growth process. As depicted in FIGS. 3F and 3H, pairs of quantum dots extinction-matched at 400 nm are also matched over a broad range of spectral wavelengths between about 300-450 nm, allowing equivalent excitation efficiency using a wide range of excitation sources. In the insets, spectra of extinction-matched quantum dot pairs are divided to emphasize the uniformity of ε over a wide range of wavelengths; this uniformity increases with growth of thicker shells as the CdS domain dominates the spectra, washing out differences arising from dissimilar cores. Note that for conventional CdSe/CdZnS ST-QDs, similar plots show differences on the order of 40-fold for different colors.

FIGS. 3I and 3J depict the most important differences between the use of size-tuned cores and composition-tuned cores for extinction matching: size-tuned cores provide little capacity for emission wavelength tuning compared with those based on alloyed cores. The maximum wavelength separation we could achieve for extinction-matched quantum dots using size-tuned cores was 35 nm due to a larger redshift induced by the CdS shell growth on smaller cores, arising from electron tunneling into the shell. See (38) Peng et al. Thus the ˜5 ML required to equalize the small core ε to that of the red core decreased the wavelength difference drastically. However we were able to achieve >150 nm spectral tunability for the ternary alloy cores, which can be further expanded into the near-infrared and into the blue spectra. This is because the extinction coefficients are similar initially, so shell growth induces similar redshifts for all of the samples. In addition, this allows the preparation of extinction-matched quantum dots that are more compact, a widely desirable attribute for many bioimaging applications. See (39) Susumu et al., (40) Smith et al., (41) Muro et al., (42) Xu et al., and (43) Chen et al. In principle, it should be possible to achieve wider spectral tunability with binary cores by employing a shell material for which electron confinement in the core is enhanced, which would reduce spectral shifting with shell growth. However the best materials that satisfy this requirement for II-VI cores (e.g. ZnSe or ZnS) have larger bandgaps and smaller lattice constants than CdS, which yield a shorter onset wavelength for extinction enhancement (<450 nm) and lower quantum yield due to lattice mismatch-induced defect formation. With the use of an alloyed or gradient shell material, it may be possible to balance all of these effects, but the structures may be more difficult to characterize and generate consistently

Methods of Matching Quantum Yield and Brightness

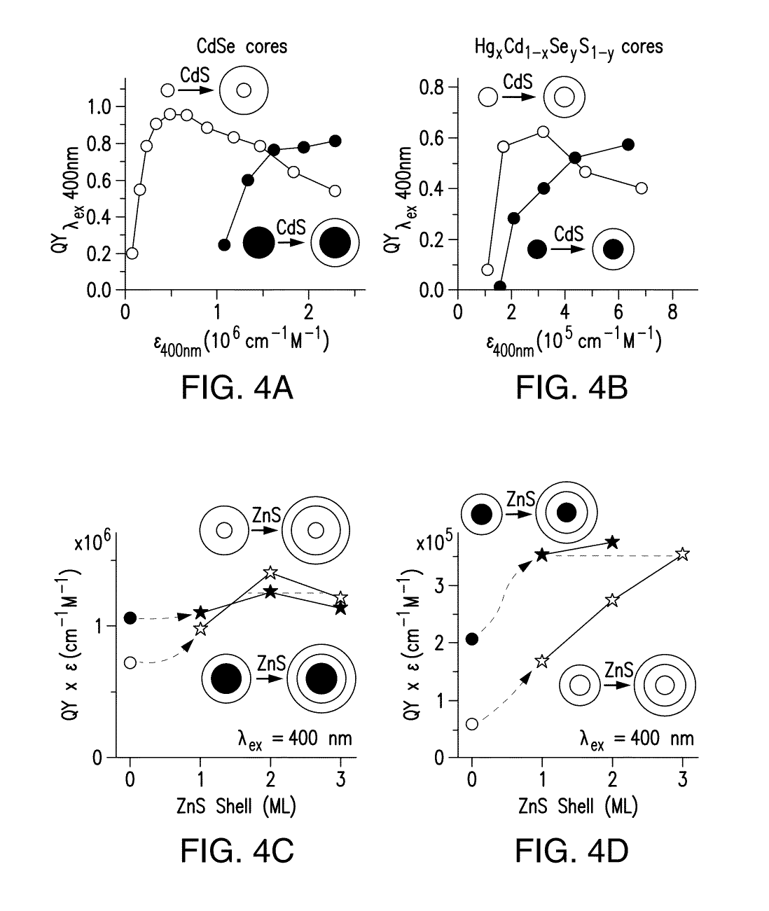

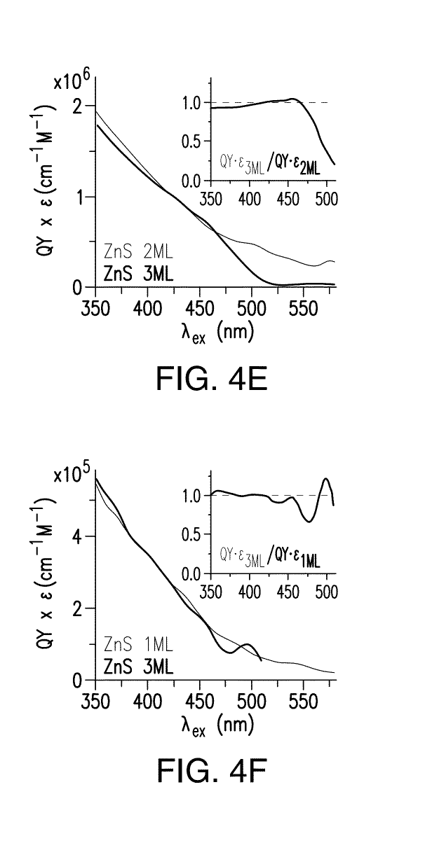

The quantum yield of a semiconductor quantum dot is largely a function of surface traps, which are localized electrostatic charges arising from non-passivated bonding orbitals that provide non-radiative decay pathways that quench fluorescence emission. See (18) Smith et al., (44) Dabbousi et al., and (45) Hines et al. While still poorly understood, it is well known that the overgrowth of a larger bandgap shell increases QY by serving as an electronic insulator to reduce electron and hole wavefunction overlap with surface traps. Thus CdS is a commonly used shell material for CdSe core nanocrystals as it strongly confines the hole to prevent access to anionic trap sites on the surface, enabling the generation of quantum dots with near unity QY at room temperature in a variety of solvents. See (43) Chen et al., (46) Chen et al., and (47) Talapin et al. However it is not sufficient alone unless thick shells are deposited, as much of the QY boost is lost after dispersion in aqueous solution due to the introduction of new surface traps from possible oxidizing adsorbates. FIGS. 4A and 4B depict trends in QY during CdS shell growth in organic solvents; the x-axes of these plots are the extinction coefficient values derived from FIG. 3. On these plots, QY increases initially with shell growth, and intersecting points can be found between any two quantum dot pairs, where they are “brightness matched,” as ε and QY values are each equal. These trends provide a simple method to achieve brightness-matched quantum dots in organic solvents, however these results do not translate after transfer to aqueous solution unless thick shells are grown, and bluer quantum dots exhibited non-monotonic increases in QY during shell growth. These problems can be overcome by deposition of a second concentric shell of ZnS, which has an even wider bandgap (3.7 eV) and strongly confines the electron, but only has a small impact on the extinction coefficient between 300-500 nm (<10% change). FIGS. 4c and 4d depict the change in quantum dot brightness with ZnS deposition: quantum dots based on size-tuned CdSe cores are brightness equalized after deposition of 2-3 monolayers of ZnS, and the quantum dots based on composition-tuned core are brightness equalized after different quantities of shell deposition. Cores with wider bandgaps required thicker shells, likely due to a lower degree of insulation provided by the shell material. FIGS. 4E and 4F depict “brightness spectra” of (QY×ε) vs. excitation wavelength for different QD colors after capping with ZnS, demonstrating brightness equalization over the 350-450 nm excitation range and spectrally uniform quantum yield when exciting below 480 nm. Similar plots for conventional ST-QDs show a mismatch in brightness in the range of 93-fold, depending on the wavelength of excitation. BE-QDs could be generated based on size-tunable CdSe cores or alloys, but again, alloys providing a much wider range of spectral tunability.

Synthesis Reproducibility

In order to ensure broad utility of this methodology to expand the optical parameters of quantum-confined colloidal particles, it is critical that the individual processes involved are highly reproducible. We explored the reproducibility by performing three independent replicates of each step involved in the generation of sets of BE-QDs with three different emission wavelengths. We note that our chemical processes were chosen specifically for high reproducibility, employing a heat-up core synthesis process rather than an injection-based nucleation method, [see (48) Chen et al.] and using shell reagents that are highly reactive and pure such that the observed shell deposition was efficient and matched expected values. See (49) Greytak et al. display the data collected from these experiments. HgₓCd₁₋ₓSe_{y}Si_{1-y} cores with three different compositions were synthesized independently three times using the two-step heat-up and mercury alloying process. These syntheses were highly reproducible: the standard deviation (SD) in wavelength for the first exciton absorption peak was between 0.58-1.2 nm for each color and the relative standard deviation (RSD) for generating a specific ε value at 400 nm was between 0.3-2.3% for each color. These ε values between different color batches were significantly different, with a p-value of 1.6×10⁻⁷ (one-way analysis of variation). The extinction coefficients were then equalized across the three colors through CdS shell growth (3.2 ML), yielding 1.2-2.8% RSD within color batches and a p-value of 15% between different color batches for the process. The QY values were then equalized through ZnS shell growth (2.4 ML), with values in chloroform varying with a 2.6-3.1% RSD within batches and p-value of 78% between different color batches. When these particles were transferred to water, the QY differences widened in dispersion, with 4.3-6.7% RSD within batches and p-value of 73% between different color batches. The resulting quantum dots in aqueous solution had 5.5-7.7% RSD in brightness values and p-value of 39% between different color batches, with a maximum of 3.0 nm SD in emission wavelength. The most variable individual process for a specific color was the QY equalization process and the most variable process for brightness equalization between different colors was the ε equalization process. Overall, we consider this to be a very high level of reproducibility and can be further improved by continuously monitoring changes in ε and QY during the growth process.

We also found that these nanocrystals undergo an “aging” process as an ensemble by slightly changing in brightness over time in aqueous solution, an effect previously observed for other quantum dots. See (50) Shea-Rohwer et al. After 8 months in storage the brightness values of green and red BE-QDs decreased by 30-40%, yielding relative brightness values for the pair that changed from 1.0-fold (equalized) to 1.17-fold. In comparison, ST-QDs with the same wavelengths as the BE-QDs diverged in brightness to a much greater degree over after 8 months in storage, with the green quantum dots decreasing in brightness by 59% and the red quantum dots increasing by 14%. The resulting brightness values were initially mismatched by 93-fold and increased in difference to 260-fold after 8 months. We attribute the improved similarity in stability of the BE-QDs to the use of shells with nearly identical composition and thickness, which are critical contributors to both quantum yield and extinction.

We further investigated how ligand coating chemistry impacts the brightness of BE-QDs. For the majority of this work we employed amphiphilic polymers to coat the nanocrystals in water, which allow the retention of the original ligands from shell synthesis on the nanocrystal surface. However recently multidentate polymers and thin ligand coatings have been employed to prepare quantum dots with a smaller hydrodynamic size more useful for many biomolecular detection applications. See (39) Susumu et al., (40) Smith et al., (41) Muro et al., (42) Xu et al., (43) Chen et al., (51) Liu et al., (52) Smith et al., and (53) Palui et al. With multidentate polymers, the quantum yield values were slightly lower and the resulting brightness values were slightly more variable (9.4% RSD in average brightness between three colors). With thiol-based ligands, quantum yields were much lower and the brightness differences between colors were more pronounced (68% average RSD between colors), as green BE-QDs exhibited drastically reduced quantum yield (20-fold reduction) compared with red ones (3-fold reduction). Further development of the shell material to prevent leakage of charge carriers to the surface for all of the colors evenly may eliminate this effect for thiol-based ligands

Single-Molecule Brightness

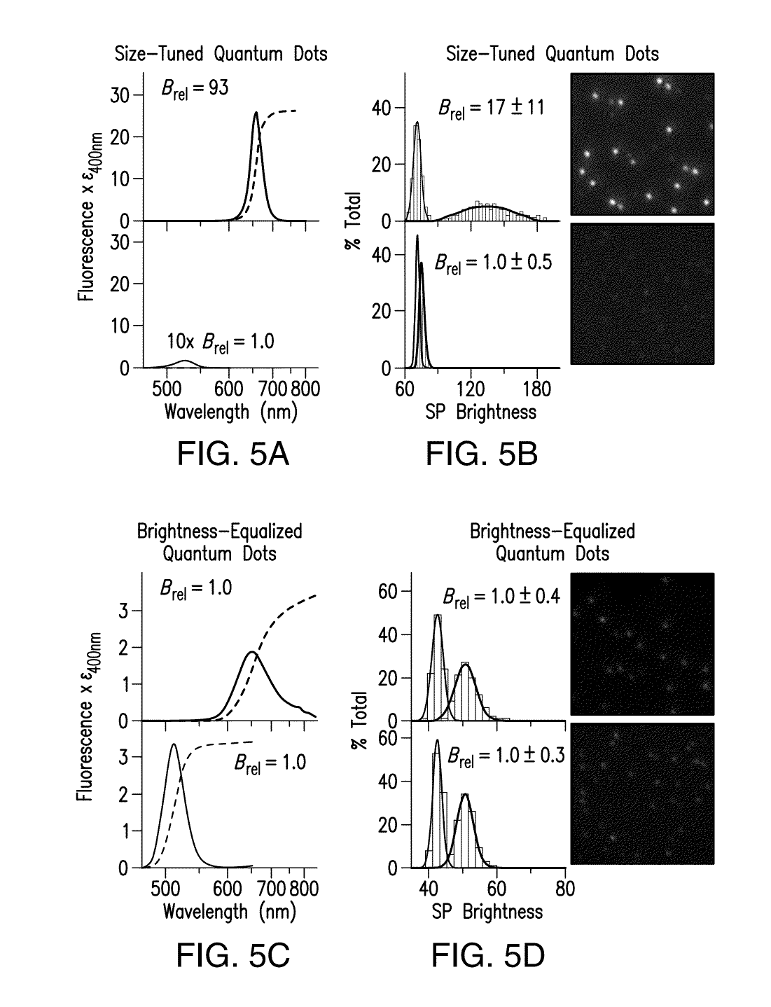

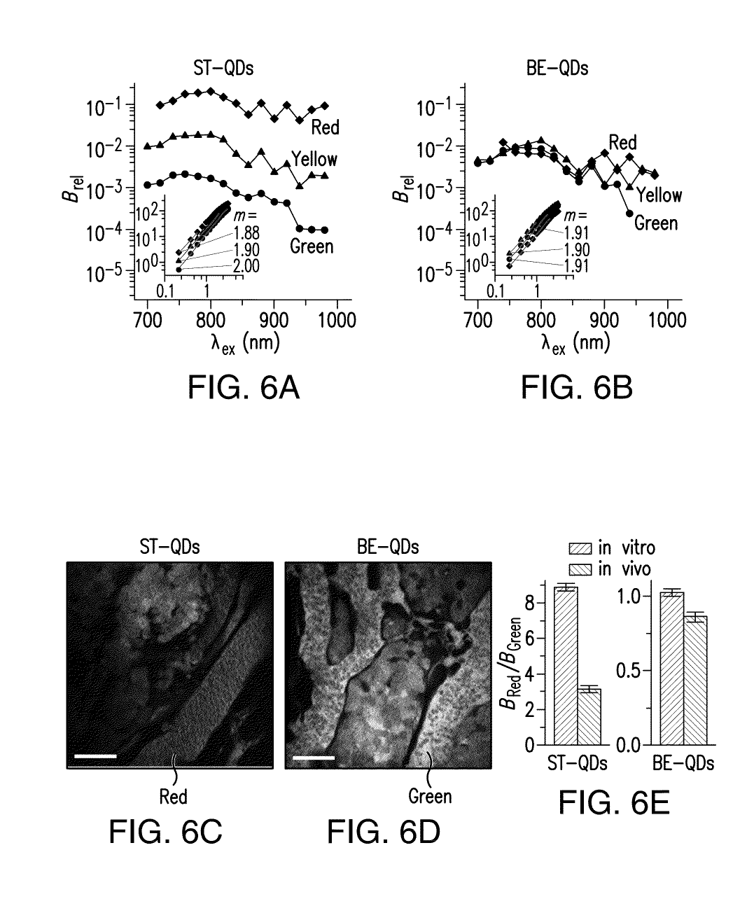

We compared the brightness of two colors of BE-QDs (525 nm and 650 nm) and two colors of conventional CdSe/CdZnS ST-QDs (525 nm and 655 nm) at the ensemble and single-molecule levels. TEM showed that all quantum dots were relatively homogeneous in diameter. All quantum dots were phase transferred to phosphate buffered saline using the same polymeric surface coating prior to measurement. FIG. 5 depicts the ensemble fluorescence spectra of these quantum dots at identical molar concentrations with excitation at 400 nm, in addition to their spectrally integrated fluorescence intensities. For the ST-QDs, the red quantum dots were 93-fold brighter than the green quantum dots. For the BE-quantum dots, the brightness values were nearly identical. We spin-coated dilute suspensions of these quantum dots onto glass coverslips and examined the brightness at the single-molecule level using epifluorescence microscopy with 400 nm excitation. Examples of integrated movie frames are shown in FIGS. 5B and 5D. Quantum dots were imaged at 19.4 frames per second and all quantum dots exhibited fluorescence intermittency (blinking). In order to determine the brightness of the “on” fluorescence state only and to eliminate particle aggregates from consideration, histograms of brightness for each quantum dot were fit to a sum a noise peak (a Gaussian) and a quantum dot signal peak (a skewed Gaussian) using algorithms based on previous reports. See (29) Arnspang et al. More than 430 single particles were identified in each sample and their “on” intensities were binned with their noise levels, as shown in FIGS. 5B and 5D. As expected, the ST-QDs exhibited widely different “on” brightness levels, however the observed 17-fold difference was smaller than that observed at the ensemble level. This may be the result of different quantum yield when exciting at high fluence or due to the slightly prolate shape of the larger quantum dots, as alignment on the substrate may have an important contribution to excitation efficiency and emission polarization. Larger quantum dots also yielded a wider dispersion of brightness levels across the population, which was in accord with the dispersion in nanocrystal radius (dr) derived from electron micrographs, as the volume dispersion scales with r²dr. Unlike the ST-QDs, the BE-QDs were very similar in histogrammed brightness levels, only differing in a slightly wider distribution for the Hg-rich QDs. We also compared these materials with commercially available Qdots composed of CdSe-based materials. Unfortunately the characterized sizes and extinction coefficients of these materials were found to differ from what was given in specification information, so interpretation of the results is difficult. Importantly, for these single-particle studies, the average excitation rate per particle (with photon flux <10 mW cm⁻²) was orders of magnitude smaller than the saturated rate of fluorescent photon emission based on a typical excited state lifetime of quantum dots (˜20-50 ns), so saturation effects are not expected to play a significant role. However lifetime differences will likely play a role in observed brightness when the populations approach saturation.

For this demonstration we prepared these particles to be as compact as possible (<6 nm) to maximize their utility for biomolecular sensing. Even smaller quantum dots could be prepared, but the brightness levels are not as precisely matched across a wide range of excitation spectra; likewise larger quantum dot sets could also be prepared, with an advantage of greater absolute brightness and narrower emission bands. Notably, the bandwidth in energy is fairly uniform across different colors of BE-QDs (e.g. see FIG. 1F), as would be expected for quantum dots with similar core sizes and size dispersions. In contrast, the bandwidth in energy for ST-QDs decreases for more red-shifted particles due to decreasing confinement of the core material with increasing size. Further bandwidth engineering can be performed by choosing material compositions with different exciton sizes. Notably, BE-QD sizes were not precisely matched between different colors, as would be expected from their different compositions (see FIGS. 2A, 2B, and 2C) that require different quantities of material for extinction and QY balancing, although their size differences were much smaller than those of ST-QDs.

Multiphoton Brightness

Quantum dots are noted for being exceptionally bright multiphoton contrast agents due to extremely large multiphoton cross sections.³³ While the nonlinear photophysics underlying the multiphoton excitation of quantum dots are still not fully understood, it has been reported that the 2-photon absorption (2PA) cross section of CdSe and CdTe nanocrystals scales roughly with r⁴ for 700-900 nm excitation. See (30) Pu et al. FIG. 6A shows the 2PA fluorescence brightness for three colors of ST-QDs excited across the 700-1000 nm range using a femtosecond pulsed laser. The plot inset shows that the quantum dots exhibit power saturation curves with an exponent in the 1.88-2.00 range, consistent with non-saturating conditions. Note that the brightness axis is given in logarithmic scale: the relative brightness of the yellow quantum dot is ˜30-fold greater than that of the green quantum dot where the curves are relatively flat (740-850 nm) and the red quantum dots are ˜220-fold brighter. At even longer wavelengths this difference reaches ˜500-fold between red and green. In comparison, three BE-QDs have substantially closer brightness levels, as shown in FIG. 6B, with a brightness difference less than 1.6-fold in the 740-850 nm range.

To demonstrate the improved capacity for quantitative 2PA fluorescence imaging in a complex tissue, we prepared two sets of multicolor quantum dots. The ST-QD set comprised a red quantum dot that had a greater brightness than the green quantum dot. The BE-QD set had a similar brightness between the two colors. Importantly, the red quantum dots for both sets were identical so that they could serve as an internal control to allow the direct comparison between the green quantum dots, which had identical emission wavelengths, differing only in particle size and brightness. We coated all quantum dots with the same polymeric coatings with a thick polyethylene glycol (PEG) shell to mask disparities in size that could contribute to different circulation times in blood, then mixed the green and red quantum dots from each set together and injected each set intravenously into mice bearing orthotopic breast carcinomas (PyMT-MMTV). As shown in FIGS. 6C and 6D, we imaged the vasculature of the tumors via intravital multiphoton fluorescence microscopy up to a depth of 50 μm, with an excitation wavelength of 780 nm, and measured the average brightness of the red and green channels for each quantum dot set. We compared the relative red/green brightness ratio in vivo with the measured in vitro values (expected values). The ST-QD pair had a measured R/G brightness ratio of 3.13, but it was expected to be 8.87. The BE-QD pair had a measured R/G brightness ratio of 0.86, with an expected value of 1.02. These results show that the BE-QDs provide a substantial improvement in predicted photon output between different colors in comparison with ST-QDs. ST-QDs yield incorrect readings of in vivo concentration, in this experiment, by a factor of 2.8, whereas that difference is reduced to <1.2 in the case of the BE-QDs. The slight remaining difference from the expected values are likely due to differences in emitted light attenuation through the tissue and uncertain levels of quantum dot saturation. The excitation power dependence onset of fluorescence saturation is much more widely dispersed for ST-QDs compared with BE-QDs (see insets in FIGS. 6A and 6B), as red ST-QDs saturate at a much lower photon flux than green ST-QDs, whereas they have much better match across colors for BE-QDs.

### EXAMPLES

The following examples further describe and demonstrate embodiments within the scope of the present invention. The Examples are given solely for purpose of illustration and are not to be construed as limitations of the present invention, as many variations thereof are possible without departing from the spirit and scope of the invention.

### Example 1

### Core Quantum Dot Synthesis

Binary CdSe and CdS and ternary CdSeS alloyed cores were synthesized from a non-injection heat-up synthesis using a cadmium carboxylate (cadmium behenate or cadmium myristate), SeO₂, and elemental S as precursors and 1-octadecene (ODE) as solvent. In a typical synthesis, CdSeₓS₁₋ₓ (0≦x≦1) QDs were synthesized by mixing Cd behenate (0.2 mmol), SeO₂ (0.2×mmol), and S (0.2(1-x) mmol) in ODE (4 mL) at room temperature and heating to ˜230° C. at a rate of ˜20° C./min. The temperature was maintained at 230° C. for ˜15 min and the reaction was quenched by decreasing the temperature to ˜100° C. and diluting with chloroform (10 mL) containing oleylamine (OLA; 0.6 mL) and oleic acid (1 mL). Finally, a mixture of acetone and methanol was added to precipitate the pure cores. Alloyed HgCdSe(S) cores were prepared via mercury cation exchange on CdSe(S) cores. Typically, CdSe cores dispersed in oleylamine were heated to 50-150° C. and mixed with mercury octanethiolate (Cd:Hg=1:2) to induce cation exchange. After a desired amount of redshift was observed in the absorption spectrum, the reaction was quenched by precipitating the particles with a mixture of acetone and methanol. Details on the chemicals and synthetic parameters for cores with different sizes and compositions are as follows in this Example.

Chemicals

Commercial sources. Cadmium oxide (CdO, 99.99+%), cadmium acetate hydrate (Cd(Ac)2.H2O, 99.99+%), mercury acetate (Hg(Ac)2, 99.999%), diethylzinc solution (Zn(Et)2, 1.0 M in hexane), selenium dioxide (SeO₂, ≧99.9%), selenium powder (Se, ˜100 mesh, 99.99%), sulfur powder (S, 99.98%), hexamethyldisilathiane ((TMS)2S, synthesis grade), 2,2′-dithiobis(benzothiazole) (99%), octanethiol (OT, >98.5%), tributylphosphine (TBP, 97%), diphenylphosphine (DPP, 98%), 1,2-hexadecanediol (HDD, 97%), N-methylformamide (NMF, >99%), tetramethylammonium hydroxide solution (TMAH, 25 wt. % in methanol), and fluorescein isothiocyanate isomer I (fluorescein, >90%) were purchased from Sigma-Aldrich. Cadmium chloride anhydrous (CdCl2, 99.99%), and zinc acetate (Zn(Ac)2, 99.98%) were obtained from Alfa Aesar. 1-octadecene (ODE, 90% tech.), oleylamine (OLA, 80-90% C18-content), decylamine (DA, 99%), oleic acid (OAc, 90% tech.), myristic acid (MAc, 99%), and 4-(4,6-di methoxy[1,3,5]triazin-2-yl)-4-methylmopholinium chloride (DMTMM) were purchased from Acros Organics. Behenic acid (BAc, 99%) was obtained from MP Biomedicals and octadecylphosphonic acid (ODPA, >99%) was purchased from PCI Synthesis. Trioctylphosphine oxide (TOPO, 99%) and trioctylphosphine (TOP, 97%) were acquired from Strem Chemicals. 750 Da monoamino-polyethylene glycol (amino-PEG) was purchased from Rapp Polymere. Solvents including chloroform, hexane, toluene, methanol, acetone were purchased from various suppliers including Acros Organics, Fisher Scientific, Macron Fine Chemicals. Streptavidin-Qdot®conjugate kit including Qdot®655 was purchased from Life Technologies. All chemicals above were used as purchased.

Cadmium Behenate (Cd(BAc)₂) and Cadmium Myristate (Cd(MAc)₂) Synthesis:

Cd(BAc)₂ was prepared using literature methods. See (55) Chen et al. and (56) Cao et al. CdCl₂ (5 mmol) was dissolved in methanol (200 mL), filtered to remove any undissolved debris, and transferred to a 500-mL dropping funnel. BAc (15 mmol) was dissolved in a mixed solvent of methanol (1.25 L) and chloroform (150 mL) with the addition of TMAH (25% wt. in methanol, ˜8 mL). The mixture was stirred for >1 h until complete dissolution of the white BAc powder, and the solution was filtered to yield a clear, colorless solution. The CdCl₂ solution was added dropwise to the BAc solution with vigorous stirring in a 2-L beaker. The entire CdCl₂ solution was added in ˜1 h and the mixture was left stirring for an additional 1 h. Cd(BAc)₂ was collected by vacuum filtration and washed three times with methanol (150-200 mL per wash) on a filter funnel. The product was dried on the funnel for several hours and then dried under vacuum at ˜50° C. overnight. Cd(MAc)₂ was synthesized using the same process except BAc was replaced with MAc and chloroform was not used to dissolve MAc.

Hg(OT)₂ Synthesis:

Hg(OT)₂ was synthesized by following literature protocols.⁴ Briefly, Hg(Ac)₂ (2 mmol) was dissolved in methanol (100 mL) and filtered. OT (6 mmol) was mixed with methanol (1 L) and KOH (6 mmol). Hg(Ac)₂ solution was added dropwise to the OT solution while vigorously stirring to produce a white Hg(OT)₂ precipitate. Hg(OT)₂ was collected by vacuum filtration and washed multiple times with methanol, and once with ether. The product was dried overnight under vacuum.

40% Octylamine-Modified Polyacrylic Acid (Amphiphol) Synthesis:

Amphipol was synthesized and purified using methods described in the literature. M.W. ˜2,911. See (58) Gohon et al.

Multidentate Polyimidazole Ligand Synthesis:

A polyimidazole ligand was synthesized using similar methods from the literature. See (59) Carbone et al. and (60) Smith et al.

Zwitterionic Bidentate Thiol Ligand Synthesis:

The thiol ligand was synthesized methods from the literature. See (61) Liu et al.

Quantum Dot Synthesis

Wurtzite (W) CdSe Core Synthesis:

W CdSe QDs were synthesized using methods of Manna et al. with minor modifications. See (62) Park et al. In a typical synthesis, a Cd precursor solution was prepared by mixing CdO (60 mg), ODPA (280 mg), and TOPO (3 g) in a 50-mL round bottom flask (r.b.f.), dried under vacuum at ˜100° C. for 1 h, and heated to ˜320° C. under nitrogen until the brown mixture became a clear colorless solution. TOP (1 mL) was then added to the Cd solution and the temperature was stabilized at a desired value for the Se precursor injection (300-365° C.). The Se precursor solution was made by sonicating a dispersion of Se powder (60 mg) in TOP (0.5 mL) until it became a clear solution. This Se/TOP solution was added with a controlled amount of 0.8 M DPP in TOP stock solution (10-100 μL). QDs were produced by injecting the Se solution into the Cd solution, and sizes were tuned by varying the injection temperature, amount of DPP/TOP stock solution, and the growth time. Detailed synthetic conditions are provided in Table 51. The QDs were purified by diluting the reaction mixture with toluene (3 mL) followed by precipitation with excess methanol (˜40 mL). After two more cycles of dissolution in toluene and precipitation with methanol, purified QDs were dissolved in hexane and stored as a pure stock solution.

Synthetic Conditions for W CdSe QDs:

The heating mantle was removed right before the Se precursor injection. Immediately after the Se injection, the solution was rapidly cooled down to ˜200° C. in ˜1 min using a stream of air to quench particle growth.

Se precursor was injected with the heating mantle attached. In 50 s, the heating mantle was removed and the solution was rapidly cooled under a stream of air.

Synthetic Conditions for W CdSe QDs

| QD | Se Injection | DPP/TOP | Growth |
|---|---|---|---|
| Diameter | Temperature | Stock | Time |
| 2.0 nm | 300° C. | 100 μL | 0 s |
| 2.4 nm | 325° C. | 100 μL | 0 s |
| 4.3 nm | 365° C. | 10 μL | 50 s |

Zinc-Blende (ZB) CdSe Core Synthesis

Diphenylphosphine Selenide (DPPSe) Synthesis:

DPPSe was synthesized by reacting DPP with Se powder in 1:1 molar ratio under nitrogen at room temperature.

2.3 nm CdSe:

CdO (0.6 mmol), TDPA (1.33 mmol), and ODE (27.6 mL) were mixed in a 250-mL r.b.f. and heated to ˜320° C. under nitrogen until the mixture became a clear colorless solution. HDA (7.1 g) was added and the temperature was stabilized at 300° C. A Se precursor solution was prepared by mixing a Se/TOP stock (1 M, 3 mL), DPPSe (52.5 mg), and TOP (4.5 mL) under nitrogen. QDs were grown by swiftly injecting the Se solution into the Cd solution with vigorous stirring using a 10-mL syringe with a wide bore (16 G) needle. 30 s after the Se injection, the heating mantle was quickly removed and the reaction solution was rapidly cooled under a stream of air. The reaction solution was divided into two 50-mL tubes and QDs were precipitated by adding a mixture of methanol (15 mL) and acetone (15 mL). QDs were then redispersed in hexane and purified by methanol extraction. Finally, purified QDs dispersed in hexane were stored as a concentrated stock solution.

3.0 nm & 4.2 nm CdSe:

CdSe QDs were synthesized using the method of Chen et al.² with some modifications. Cd(BAc)₂ (for 3.0 nm CdSe; 0.2 mmol) or Cd(MAc)₂ (for 4.2 nm CdSe; 0.2 mmol), SeO₂ (0.2 mmol), HDD (0.2 mmol), and ODE (4 mL) were mixed in a 50-mL r.b.f. and dried under vacuum at ˜100° C. for 2 hours. Then the temperature was raised to 230° C. at a rate of ˜20° C./min under nitrogen. The solution color changed from colorless to pale yellow at ˜190° C. indicating CdSe nucleation. After reaching 230° C., the temperature was maintained for 15 min. QD growth was quenched by removing the heating mantle. When cooled to ˜110° C., the reaction solution was mixed with chloroform (10 mL) containing OAc (1 mL) and OLA (0.6 mL). Purification was performed by precipitating the QDs through the addition of a mixture of methanol (15 mL) and acetone (15 mL). QDs were redispersed in hexane (˜20 mL) and extracted twice with methanol (5-10 mL per cycle) followed by precipitation with excess methanol. Finally, QDs were washed with a few mL of acetone to ensure that there was no methanol remaining, and dispersed in hexane as a stock solution.

CdSe_{0.42}S_{0.58} and CdSe_{0.89}S_{0.11} Alloy Core Synthesis

CdSeS alloy QDs were synthesized and purified by following the same protocol used for 3.0 nm CdSe QDs with a difference of using controlled ratios of the two chalcogen precursors, SeO₂ and elemental S, instead of using SeO₂ alone. For CdSe_{0.42}SO 58 core synthesis, Cd(BAc)₂ (0.2 mmol), SeO₂ (0.066 mmol), S (0.134 mmol), and HDD (0.2 mmol) were reacted in ODE (4 mL) (Se:S=0.33:0.67). For CdSe_{0.89}S_{0.11} core (HgCdSeS-1) synthesis, Cd(BAc)₂ (0.6 mmol), SeO₂ (0.4 mmol), S (0.2 mmol), and HDD (0.6 mmol) were reacted in ODE (12 mL) (Se:S=0.67:0.33). Elemental analysis using an inductively coupled plasma-optical emission spectrometry (ICP-OES) system was used to confirm the Se-to-S ratios.

CdS Core Synthesis

CdS QDs were synthesized by adjusting the methods of Cao and coworkers. See (55) Chen et al. and (56) Cao et al.

2.0 nm CdS:

Cd(BAc)₂ (0.2 mmol), S (0.2 mmol), HDD (0.2 mmol), and ODE (4 mL) were mixed in a 50-mL r.b.f. and dried under vacuum at ˜100° C. for 2 hours. Then CdS QDs were grown by raising the temperature to 230° C. at a rate of ˜20° C./min under nitrogen. The temperature was maintained at 230° C. for 15 min before cooled to ˜110° C. for purification. The purification procedure was the same as for the 3.0 nm CdSe synthesis.

2.8 nm CdS:

TBPS was synthesized by sonicating S powder in TBP under nitrogen with 1:1 S-to-TBP molar ratio. Cd(BAc)₂ (0.2 mmol), HDD (0.2 mmol), and ODE (3.2 mL) were mixed in a 50-mL r.b.f. and dried under vacuum at ˜100° C. for 2 hours. TBPS (1.25 M) in an ODE stock solution (0.8 mL) was injected under nitrogen and the temperature was increased to 230° C. at a rate of ˜20° C./min. CdS nucleated at ˜110° C. The temperature was maintained at 230° C. for 30 min before cooled down to ˜110° C. for purification. The purification procedure was the same as for the 3.0 nm CdSe synthesis.

3.7 nm CdS:

A solution of S in ODE was prepared by mixing S powder (1 mmol) with ODE (10 mL) under nitrogen and heating to ˜200° C. until the mixture became a clear colorless solution. Cd(BAc)₂ (0.2 mmol), S (0.2 mmol), 2,2′-dithiobisbenzothiazole (0.0625 mmol), HDD (0.2 mmol), and ODE (3.4 mL) were mixed in a 50-mL r.b.f. and dried under vacuum at ˜100° C. for 2 hours. Then CdS QDs were grown by heating the solution to 230° C. at a rate of ˜20° C./min under nitrogen. After keeping the temperature at 230° C. for 15 min, the dropwise addition of 0.1 M S/ODE stock solution (1 mL) over ˜40 min allowed additional particle growth.

HgCdSeS Alloy Core Synthesis

HgCdSeS QDs were prepared through Hg cation exchange reactions on CdSe or CdSeS QDs using method developed by Smith & Nie with several modifications. See (57) Smith et al. and (59) Carbone et al.

Hg Exchange Using Hg(OT)₂:

A CdSe or CdSeS QD stock in hexane (˜100 nmol in a few mL of hexane) was injected into OLA (5 mL) under nitrogen and hexane was evaporated completely under vacuum at 40-50° C. Hg exchange was initiated by adding Hg(OT)₂ (2× excess of total Cd atoms) either as powder or as a solution in OLA (0.1 M). The reaction rate was adjusted by gradually increasing the temperature (40-150° C.). Changes in the bandgap energy and the absorption extinction were carefully monitored by removing precise aliquot volumes (typically 200 μL, then diluted 10-fold with chloroform) every 3-5 min to measure the UV-vis-NIR absorption spectrum. Detailed reaction parameters are provided in Table S2. When a desired amount of redshift was induced, reaction quenching and purification were performed by precipitating the QDs through the addition of a 1:1 mixture of methanol/acetone (˜30 mL total). The QD precipitate was washed two times with methanol then finally dispersed in hexane to be used as a stock solution. The stock solution was left at room temperature for at least a day before use in core/shell QD synthesis because there was typically an additional 10-15 nm redshift in the absorption spectra over time due to internal diffusion of Hg ions.

Hg Exchange Using Hg(Ac)₂:

CdSe QDs (100-200 nmol) were dispersed in a 0.2 M solution of OLA in chloroform (4-5 mL). A 0.1 M Hg(Ac)₂(OLA)₂ stock solution was prepared by dissolving Hg(Ac)₂ (0.5 mmol) in a 0.2 M OLA solution in chloroform (5 mL). Hg exchange was initiated by swiftly injecting the Hg(Ac)₂(OLA)₂ solution (3× excess of total Cd atoms) into the CdSe QD solution under vigorous stirring. The extent of Hg exchange was carefully monitored by taking absorption spectra of aliquots (˜100 μL, then diluted 10-fold with chloroform) every 3-5 min. After the desired amount of redshift, the reaction was quenched by adding OT (˜100 μL) and precipitating the QDs with a 1:1 mixture of methanol/acetone (˜20 mL total). QDs were further purified by three cycles of redispersion in hexane (˜10 mL) with OLA (˜200 μL) and OAc (˜100 μL) and precipitation with methanol/acetone. Finally, the QDs were dispersed in hexane and stored as a stock solution for at least a day before use in core/shell QD synthesis.

Synthetic Conditions for HgCdSeS Cores

| CdSeS QD | Hg | | | | | | |
|---|---|---|---|---|---|---|---|
| Diameter | Precursor | Solvent | Temp. | Reaction | λ_{Abs} | λ_{Abs} | |
| (Amount) | (Amount) | (Amount) | (° C.) | Time | (CdSeS) | (HgCdSeS) | |
| 2.3 nm | Hg(OT)₂ | OLA | 50 | 15 min | 481 nm | ^{a} 520 | nm |
| (CdSe) | (24 μmol) | (5 mL) | | | | | |
| (100 nmol) | | | | | | | |
| 2.3 nm | Hg(OT)₂ | OLA | 100 | 120 min | 481 nm | ^{b} 565 | nm |
| (CdSe) | (24 μmol) | (5 mL) | | | | | |
| (100 nmol) | | | | | | | |
| 2.3 nm | Hg(Ac)₂ | CHCl₃ | r.t. | 30 min | 481 nm | ^{c} ~730 | nm |
| (CdSe) | (36 μmol) | (5 mL) | | | | | |
| (100 nmol) | | | | | | | |
| 3.0 nm | Hg(Ac)₂ | CHCl₃ | r.t. | 10 min | 532 nm | ^{d} 690 | nm |
| (CdSe) | (78 μmol) | (10 mL) | | | | | |
| (100 nmol) | | | | | | | |
| 2.9 nm | Hg(OT)₂ | OLA | 40 | 30 min | 513 nm | ^{e} 541-543 | nm |
| (CdSe_{0.89}S_{0.11}) | (48 μmol) | (5 mL) | | | | | |
| (100 nmol) | | | | | | | |
| 2.9 nm | Hg(OT)₂ | OLA | 120 | 55 min | 513 nm | ^{f} 562-564 | nm |
| (CdSe_{0.89}S_{0.11}) | (48 μmol) | (5 mL) | | | | | |
| (100 nmol) | | | | | | | |
| 2.3 nm | Hg(OT)₂ | OLA | 50 | 15 min | 481 nm | ^{a} 520 | nm |
| (CdSe) | (24 μmol) | (5 mL) | | | | | |
| (100 nmol) | | | | | | | |
| 2.3 nm | Hg(OT)₂ | OLA | 100 | 120 min | 481 nm | ^{b} 565 | nm |
| (CdSe) | (24 μmol) | (5 mL) | | | | | |
| (100 nmol) | | | | | | | |

^{a, b} HgCdSeS cores in FIG. 3;
^{c} HgCdSeS (x = 0-1) core in FIG. 2B;
^{d} HgCdSe core for QD750 in FIGS. 1E and 1F;
^{e} HgCdSeS-2;
^{f} HgCdSeS-3.
r.t. = room temperature

### Example 2

### Cadmium Sulfide and Zinc Sulfide Shell Growth

Both CdS and ZnS shells were grown following conventional layer-by-layer shell growth protocols used in core/shell QD synthesis. Cadmium oleate in ODE-decylamine-trioctyphosphine (TOP), zinc acetate in OLA, and hexamethyldisilathiane ((TMS)₂S) in TOP were used as shell precursors for Cd, Zn, and S, respectively. For the first monolayer of CdS shell growth on HgCdSe(S) cores, Cd and S precursors that were free from TOP (Cd oleate in ODE-decylamine and (TMS)₂S in ODE), were used because TOP can degrade bare HgCdSe(S) cores due to the strong binding affinity of TOP to Hg ions. In a typical synthesis, 50-100 nmol of pure core QDs dispersed in ODE/OLA solvent (2:1 v/v) were heated up to desired temperature for the shell growth: 120-190° C. for CdS shell growth depending on the core size and the shell thickness and ˜190° C. for ZnS shell growth. In each layer-by-layer shell growth cycle, the S precursor was added dropwise and allowed to react for 15-20 min, and then the Cd or Zn precursor was added dropwised and allowed to react for 15-20 min. To prevent homogeneous nucleation of shell materials, the CdS shell was grown with 0.8 monolayer (ML) increments (80% of total precursors needed to grow 1 ML of shell) per cycle instead of 1 ML. The ZnS shell was grown in 0.5 ML steps so that 2 cycles of S—Zn addition were needed to grow 1 ML. The quantities of precursors needed to grow each monolayer were calculated using the single monolayer thickness of ˜0.3 nm which is the thickness of one CdS layer along the (100) lattice direction of the zinc-blende CdS crystal. A precisely measured aliquot (200 μL) was withdrawn and diluted 10× in chloroform after each shell growth cycle to monitor the extinction coefficient increase. The reaction was quenched by decreasing the temperature and precipitating the nanocrystals with acetone. Detailed reaction conditions for shell growth are provided in this example as follows.

CdS and ZnS Shell Growth

CdS and ZnS shell growth was performed using a layer-by-layer shell growth protocol developed by Bawendi and coworkers with some modifications. See (63) Greytak et al.

Cd Precursor Solution:

A Cd precursor solution was prepared by mixing CdO (1 mmol), OAc (2.1 mmol), and ODE (3.9 mL) and heating to ˜250° C. under nitrogen until the brown mixture became a clear solution. After cooling to ˜100° C., DA (2 mmol) was added. Then the solution was diluted 1:1 with TOP.

Zn Precursor Solution:

A Zn precursor solution was prepared by dissolving Zn(Ac)₂ (1 mmol) in OLA (10 mL) under nitrogen.

S Precursor Solution:

A S precursor solution was prepared by dissolving (TMS)₂S (0.5 mmol) in TOP (5 mL) under nitrogen.

Layer-by-Layer Shell Growth:

To prevent homogeneous nucleation of shell materials, CdS shell was grown as increments of 0.8 ML instead of 1 ML. 1 ML thickness was set to ˜0.3 nm which is the thickness of a single CdS layer along the (100)_{ZB} direction. The amount of precursors needed was calculated based on the volume increase by the shell growth in a single monolayer and the total number of cores in the solution. In a typical reaction, a purified core stock in hexane (50-100 nmol) was injected into a mixed solvent of ODE (2 mL) and OLA (1 mL) in a 50-mL r.b.f. and hexane was completely evaporated under vacuum at 40-50° C. Next, the solution was heated under nitrogen to the temperature used for the first 0.8 ML shell growth (typically 120-130° C. for 2-3 nm cores and HgCdSeS cores, and 150-170° C. for >4 nm cores). An aliquot (200 μL) was withdrawn using a glass microsyringe and diluted 10-fold in chloroform to monitor the reaction. The S precursor for the first 0.8 ML shell was dropwise added within 3-5 min and allowed to react for 15-20 min. The same amount of Cd precursor was added in the same manner and allowed to react for another 15-20 min to complete the first cycle. Another aliquot (200 μL) was withdrawn and diluted 10-fold in chloroform to measure the absorption and emission spectra, fluorescence quantum yield, and extinction coefficient. The 0.8 ML shell growth cycle was repeated as desired. The reaction temperature was raised stepwise by ˜10° C. between each cycle until reaching a maximum of ˜190° C. Aliquots were withdrawn after each cycle to monitor the optical property changes during shell growth.

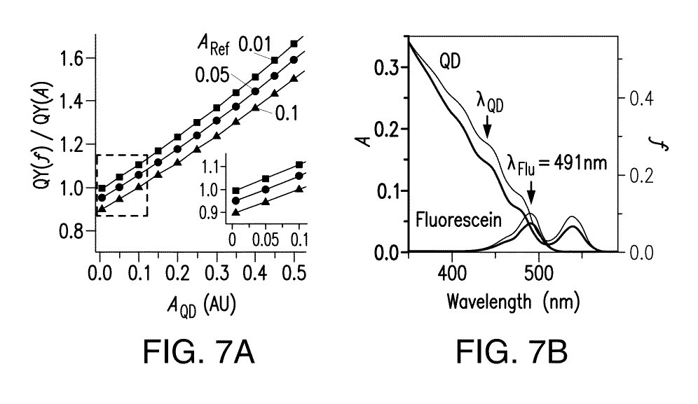

After growing a desired amount of CdS shell, the metal precursor was switched to Zn to grow the ZnS shell, which was grown in either 0.5 ML (in FIG. 4) or 0.8 ML (in Supplementary FIGS. 7 and 9) steps. The reaction temperature for ZnS shell growth was 200-220° C. Aliquots were similarly withdrawn after each 1 ML (in 0.5 ML step growth) or 0.8 ML (in 0.8 ML step growth) of shell growth.

The reaction was quenched by reducing the temperature. For purification, the reaction solution was diluted 2-3 fold in chloroform in a centrifuge tube and the QDs were precipitated by adding acetone. QDs were redispersed in chloroform and centrifuged at 7,000 g for 10 min to remove any undissolved byproducts. Then this chloroform solution was used for optical analysis and phase transfer.

First Monolayer of CdS Shell Growth on HgCdSe Cores Using TOP-Free Cd & S Precursor Solution:

Because of the strong binding affinity of TOP toward mercury ions, TOP could degrade bare HgCdSeS QDs by extracting Hg ions out of the structure. Such extraction was accelerated at elevated temperatures. Thus, the first monolayer of CdS shell needed to be grown in a TOP-free solution and at relatively low temperature. The first 0.8 ML portion of TOP-free S precursor was added dropwise starting at ˜50° C. while slowly raising the temperature up to 120-130° C. in ˜5 min. After allowing the S precursor to react for 15-20 min at 130° C., TOP-free Cd precursor for the first 0.8 ML shell was added dropwise at ˜140° C. and allowed to react for another 15-20 min. Once HgCdSeS QDs were passivated by a full monolayer of CdS shell, they were stable against TOP so that the regular TOP-containing precursors could be used for the further shell growth.

A TOP-free Cd precursor solution was prepared by mixing CdO (1 mmol), OAc (2.1 mmol), and ODE (8.9 mL) and heating to ˜250° C. under nitrogen until the brown mixture became a clear solution. The solution was cooled to ˜100° C. and DA (2 mmol) was added. The solution was then cooled to room temperature.

A TOP-free S precursor solution was prepared by dissolving (TMS)₂S (0.5 mmol) in ODE (5 mL) under nitrogen.

### Example 3

### Quantum Dot Phase Transfer

Amphipol coating: Core/shell QDs were transferred to water by coating with an amphiphilic polymer (amphipol, 40% octylamine-conjugated polyacrylic acid, M.W. ˜2,900). Typically, purified core/shell QDs dispersed in chloroform (˜1 nmol/mL, 2-10 mL) were mixed with 2,000-2,500× molar excess amphipol. Then chloroform was slowly evaporated under vacuum while vigorously stirring the mixture. After removing chloroform completely, 10 mM NaOH solution in distilled water (2-3 mL/nmol of QD) was added and stirred for several hours until the amphipol-coated QDs were fully dissolved. Finally, the solution was centrifuged to remove any undissolved QD aggregates. For PEG conjugation, amphipol-coated QDs were dispersed into 1× phosphate buffered saline (PBS) and further purified using size-exclusion chromatography and dialysis to remove free amphipol polymers. The carboxylic acid groups on the surface of amphipol-coated QDs were reacted with 40,000× molar excess of monoamino-PEG (750 Da) in PBS using 4-(4,6-dimethoxy-1,3,5-triazin-2-yl)-4-methylmorpholinium chloride (DMTMM) as the coupling reagent. Finally, PEG-coated QDs were purified by dialysis to remove excess amino-PEG and other impurities. Further details on QD phase transfer are provided in this Example as follows.

QD Phase Transfer with Amphiphilic Polymers.

A purified core/shell QD dispersion in chloroform (˜1 nmol/mL, 2-10 mL) was transferred to a vial with a stir bar. In a separate vial, amphipol (˜200 mg) was dissolved in chloroform (10 mL) at room temperature. While vigorously stirring the QD dispersion, a 2,000-2,500× molar excess of amphipol was added dropwise. The vial was sealed with a septum screw cap and placed in a vacuum desiccator with a puncture on the cap using a disposable needle (20-22 G). Chloroform was slowly evaporated overnight under house vacuum while vigorously stirring the solution. After completely removing chloroform, 10 mM sodium hydroxide solution in distilled water was added (2-3 mL/nmol of QD) and stirred for several hours until amphipol-coated QDs were fully dispersed. Finally, the solution was centrifuged at 7,000 g for 10 min to remove any QD aggregates and used in optical characterization including brightness measurements in solution and at the single molecule level. For intravital imaging experiment, these amphipol-coated QDs were purified using a size-exclusion column and dialysis. Typically, 30-40 nmol of amphipol-coated QDs in 1× phosphate buffered saline (PBS) was injected into a GE AKTAprime plus chromatography system using a Superose 6 column with PBS eluent at a flow rate of 0.5 mL/min. This separated amphipol-coated QDs with most of the free amphipol micelles. Then, these QDs were further purified by dialysis for 36 h in PBS using a 50 kDa dialysis tube.

PEG Conjugation on Polymer-Coated QDs.

Amphipol-coated QDs show strong nonspecific binding in biological systems due to the negatively charged carboxylic acid groups covering the surface. Therefore, for the intravital multiphoton imaging experiments, amphipol-coated QDs were conjugated with amino-polyethylene glycol (amino-PEG). PEG coating was performed by following a protocol in the literature. See (59) Carbone et al. Typically, amphipol-coated QD solutions in 1×PBS (˜1 nmol/mL, ˜10 mL) were mixed with 40,000× molar excess of 750 Da amino-PEG in DMSO (˜0.5 mL) at room temperature. Then, a 25,000× molar excess of freshly prepared solution of DMTMM in DMSO (0.5 M) was injected into the QD-amino-PEG solution and stirred at room temperature for 30 min. This DMTMM addition and reaction was repeated 4 more times to maximize the PEG conjugation on QD surface. The reaction was quenched by adding 1M Tris buffer (pH ˜8.5), and QDs were purified by dialysis in PBS for 24 h. Finally, PEG-coated QDs in PBS were centrifuged at 7,000 g for 10 min to remove any aggregates and filtered using a 200 μm pore-size syringe filter.

QD Phase Transfer with Multidentate Polymers.

Purified core/shell QDs dispersed in hexane were phase transferred to NMF with the addition of TMAH (100 equivalent to the QD surface atoms). The resulted OH-capped QDs in NMF were then mixed with a multidentate polymer (5 equivalent of to the QD surface atoms). The mixture was stirred for 2 h at 50° C. under N₂. To remove excess free ligands and organic solvent, the QDs dispersion was first diluted with 50 mM sodium borate buffer (pH 8.5) and re-concentrated using an Amicon Ultra centrifugal filter (50 kDa MWCO). This dilution-concentration cycle was performed 4 more times.

QD Phase Transfer with Hydrophilic Thiols.

Purified QDs in CHCl₃ were mixed with an aqueous solution of the thiol ligand. The biphasic mixture was stirred at 50° C. for 2 h under N₂. Phase transfer from organic phase to aqueous phase was indicated by disappearance of fluorescence in the CHCl₃ phase. To remove excess free ligands and organic solvent, the QDs dispersion was first diluted with 1×PBS (pH 7.4) and then re-concentrated using an Amicon Ultra centrifugal filter (50 kDa MWCO). This dilution-concentration cycle was performed 4 more times.

### Example 4

### Instrumentation

Absorption spectra were obtained using an Agilent Cary 5000 UV-Vis-NIR spectrophotometer. Fluorescence and PLE spectroscopy were obtained with a Horiba NanoLog spectrofluorometer. TEM images were acquired using a JEOL 2010 LaB₆ high-resolution microscope. ICP-OES was performed using a PerkinElmer Optima 2000DV instrument. Single particle fluorescence microscopy was performed using a Zeiss Axio Observer.Z1 inverted microscope with 100×1.45 numerical aperture Plan-Fluar objective with halogen lamp illumination. In vitro multiphoton fluorescence measurements were performed using a Zeiss 710 confocal scanning Axio Observer.Z1 inverted microscope with 10×0.30 numerical aperture Plan-Neofluar objective with tunable Mai-Tai Ti-Sapphire laser excitation. Additional details are provided in this Example as follows.

UV-Vis-NIR Absorption Spectroscopy.

Absorption spectra of quantum dot solutions were obtained using a Agilent Cary 5000 UV-Vis-NIR spectrometer. If the solution was highly concentrated (e.g. QD solutions for elemental analysis), an aliquot was diluted 10 or 20 fold so that their absorbance was in the dynamic range of the spectrometer (absorbance <4) in the entire spectral range (typically 200-800 nm).

Fluorescence and Photoluminescence Excitation (PLE) Spectroscopy.

Fluorescence and PLE spectra of a QD dispersion were obtained using a Horiba NanoLog spectrofluorometer. Dispersions were diluted enough to eliminate self-quenching of fluorescence (typically, absorbance @ 490 nm<0.1). Signal acquisition conditions such as scan time, slit widths, and number of scans were adjusted so that the brightest sample was not saturating the detector (photomultiplier tube) and all spectra showed sufficiently high signal-to-noise ratios. Raw fluorescence signal measured by the detector was corrected by both the wavelength-dependent detector sensitivity factor provided by the manufacturer and the excitation power fluctuation monitored by a built-in photodiode before they were used in fluorescence quantum yield and brightness calculations. PLE spectra were usually obtained by fixing the detection wavelength at the fluorescence peak maximum scanning the excitation wavelength from ˜300 nm up to 10-30 nm less than the detection wavelength.

Transmission Electron Microscopy (TEM).

TEM images of QDs were obtained using a JEOL 2010 LaB₆ high-resolution microscope in the Frederick Seitz Materials Research Laboratory Central Research Facilities at the University of Illinois. Samples were prepared by placing a drop of dilute QD solution in hexane or chloroform on an ultrathin carbon film TEM grid (Ted Pella, Product#01824) and then wicking the solution off with a tissue.

Inductively Coupled Plasma-Optical Emission Spectrometry (ICP-OES).

Elemental analysis was performed with a PerkinElmer Optima 2000DV ICP-optical emission spectrometer in the Microanalysis Laboratory at the University of Illinois. Samples were prepared by digesting QDs with nitric acid under high pressure (60 bar) in a PerkinElmer/Anton Parr Multiwave 3000 microwave digester. Typically, a concentrated well-purified QD solution in hexane (band edge absorption near 30-40) was prepared and its absorption spectrum was carefully measured to calculate the extinction coefficient. Then, the solution (1 mL) was transferred to a Teflon tube and hexane was completely evaporated under nitrogen flow. Three identical samples were prepared simultaneously for a precise measurement. QDs were digested into ions in the microwave reactor and the entire product was diluted to exactly 20 mL in distilled water before injection into the ICP-OES spectrometer.

Fluorescence Microscopy.

All samples were imaged via wide-field illumination on a Zeiss Axio Observer.Z1 inverted microscope with a 100×1.45 NA alpha Plan-Fluar oil immersion microscope objective with 100 W halogen lamp illumination. Excitation light was filtered using a 390/40 bandpass filter (Semrock Inc.), and emission light was filtered with a 496 longpass filter (Semrock Inc.). Images were acquired using a Photometrics eXcelon Evolve 512 EMCCD through Zeiss Zen software. All samples were uniformly excited and data was collected for 30 seconds at a rate of 19.4 frames/s. Excitation power was acquired using a PM121 optical power meter (Thor Labs).

Multiphoton Fluorescence Brightness Measurement.

All samples were measured using a Zeiss 710 confocal scanner Azio Observer.Z1 inverted microscope with a 10×0.30 NA EC Plan-Neofluar microscope objective with tunable Mai-Tai Ti-Sapphire laser (Spectra Physics) excitation. Laser power was acquired using a PM121 optical power meter. Spectrally resolved emission spectra were acquired using a Zeiss 34-Channel QUASAR detection unit.

### Example 5

### Extinction Coefficient Measurements of Cores

Extinction coefficients, ε (cm⁻¹M⁻¹), of CdSe, CdS, and CdSeS cores were measured using the Beer-Lambert law of absorbance, Equation 3,

$$ɛ = \frac{A}{l \cdot {c}_{QD}} \qquad Equation 3$$

where A is the absorbance (unitless), 1 is the path length (cm) of the cuvette, and c_{QD} is the concentration of QDs (M). A of a core solution was measured using a UV-vis absorption spectrophotometer. Typically, a 0.5 cm path length cuvette (1=0.5 cm) was used. c_{QD} was derived by combining information from two independent measurements: the average particle radius, r (nm), from TEM and elemental concentration of Cd in solution, c_{Cd} (M), from ICP-OES. The average number of Cd atoms per core QD, n_{Cd}, was calculated using r from the TEM, Equation 4:

$${n}_{Cd} = \frac{\frac{4 π}{3} {r}^{3} \cdot {d}_{Bulk} \cdot {N}_{A}}{M} \qquad Equation 4$$

where M is the molecular weight of the material and N_{A} is the Avogadro constant (6.022×10²³ mol⁻¹), based on the assumption that all particles are spherical and have the same density as the bulk material, d_{Bulk}. Then c_{QD} can be calculated from both c_{Cd} and n_{Cd} as, Equation 5,

$${c}_{QD} = \frac{{c}_{Cd}}{{n}_{Cd}} \qquad Equation 5$$

The value of ε for HgCdSe(S) alloy cores was acquired by carefully measuring the difference in the absorption spectra before and after mercury cation exchange, based on the assumption that the total number of particles was conserved during the reaction. Additional information on the ICP-OES analysis is provided in Example 5, above, and detailed descriptions for calculations are provided in this Example as follows.

Calculation of Extinction Coefficient (ε) and Absorption Coefficient (α)

Extinction coefficients, ε (cm⁻¹M⁻¹), of QDs were calculated using the Beer-Lambert law of absorbance described in equation 6,

$$ɛ = \frac{A}{l \cdot {c}_{QD}} \qquad Equation 6$$

where A is the absorbance of a QD solution (unitless), I is the path length (cm), and c_{QD} is the concentration of QD (M). A of a QD solution was directly measured using UV-vis-NIR absorption spectrophotometry. I was determined by the dimension of the cuvette holding the solution in the beam path. c_{QD} was derived from two independent measurements: average QD size (radius), r (nm), obtained by transmission electron microscopy (TEM) and elemental concentration of Cd in the solution, c_{Cd} (M), acquired from elemental analysis. Then, r is used to calculate the average number of Cd atoms in a single QD, n_{Cd}, relying on the assumption that all QDs are spherical and have density of the bulk material, d_{Bulk}, as expressed in Equation 7,

$${n}_{Cd} = \frac{\frac{4 π}{3} {r}^{3} \cdot {d}_{Bulk} \cdot {N}_{A}}{M} \qquad Equation 7$$

where, M is the molecular weight of the material (g·mol⁻¹) and NA is the Avogadro constant (6.022×10²³ mol⁻¹). Then c_{Cd} can be converted to c_{QD} by Equation 8,

$${c}_{QD} = \frac{{c}_{Cd}}{{n}_{Cd}} \qquad Equation 8$$

The absorption coefficient, α (cm⁻¹), was then derived from the absorption extinction coefficient by the relationship given in Equation 9. See (64) Jasieniak et al.

$$\begin{matrix}Equation 9 & \\ α = \frac{1000 \cdot ln ( 10 )}{\frac{4 π}{3} {r}^{3} {N}_{A}} ɛ & ( 4 )\end{matrix}$$

ε and α of CdSe, CdS and CdSeS cores were obtained by carrying out the above steps. Whereas, those of HgCdSe(S) alloy cores and all core/shell QDs were acquired by carefully measuring the changes in absorption spectra during Hg cation exchange and shell growth reactions, respectively, based on the assumption that total QD concentration remains constant through the reaction.

### Example 6

### Quantum Yield Measurements

For fluorescence QY measurements, a dilute QD sample (absorbance ˜0.05 at 491 nm) was prepared and its absorption, fluorescence, and photoluminescence excitation (PLE) spectra were acquired. The same set of spectra were acquired for a reference (fluorescein in 0.1 M NaOH, QY=92%). The relative QY was calculated using the following Equation 10.

$$\frac{{Φ}_{f , QD} ( {λ}_{ex , QD} )}{{Φ}_{f , Ref} ( {λ}_{ex , Ref} )} = \frac{\frac{{FL}_{QD} ( {λ}_{ex , QD} )}{{A}_{f QD} ( {λ}_{ex , QD} )}}{\frac{{FL}_{Ref} ( {λ}_{ex , Ref} )}{{A}_{f Ref} ( {λ}_{ex , Ref} )}} \frac{{n}_{QD}^{2}}{{n}_{Ref}^{2}} \qquad Equation 10$$

where Φ_{L} is the fluorescence QY, FL is the total fluorescence intensity (the integrated area of the emission spectrum in wavelength scale) with excitation at λₑₓ normalized by the intensity of the excitation light, A_{f} is the absorption factor (or absorptance) at λₑₓ, and n is the refractive index of the solvent. A_{f} is the fraction of incident light that is absorbed by the sample which is expressed as Equation 11.

A_{f}=1−T=1−10^{-A} Equation 11

where T and A are the transmittance and the absorbance, respectively. It should be noted that A_{f} is proportional to the number of photons absorbed by the sample whereas A is a logarithmic ratio. Therefore, A_{f} should be used for accurate calculation of relative QY, not A. Using A_{f} instead of A is especially important for excitation wavelength dependent QY calculations when the excitation wavelength used for QDs and the reference are different. Details on QY calculations are described further in this Example as follows.

### Quantum Yield Measurements

Detailed mathematical formulations and experimental protocols for fluorescence quantum yield (QY) measurements are well described in the literature. See (64) Jasieniak et al., (65) Demas et al., and (66) Grabolle et al. The QYs of our QD samples were obtained by following standard relative QY measurement protocols described in those literature reports. This section briefly covers the basic equations necessary for QY calculation and discusses in detail the protocols for excitation energy-dependent QY measurement of QD samples.

### Relative QY Calculation

QY of a fluorophore (Φ_{f}) is defined as the ratio of the number of emitted photons (N_{Em}) to the number of absorbed photons (Nabs) as Equation 12. See (65) Demas et al.

$${Φ}_{f} = \frac{{N}_{Em}}{{N}_{Abs}} \qquad Equation 12$$

QY of a fluorescent sample is often determined by comparing its fluorescence with that of a reference with known QY (e.g. molecular dyes) both measured using the same instrumental setup. The ratio between the QY of a sample excited at λ_{Ex,x} (Φ_{f,x}(λ_{Ex,x})) and that of a reference excited at λ_{EX,Ref} (Φ_{f,Ref}(λ_{Ex,Ref})) can be given using Equation 13.

$$\frac{{Φ}_{f , x} ( {λ}_{Ex , x} )}{{Φ}_{f , Ref} ( {λ}_{Ex , Ref} )} = \frac{\frac{{F}_{x} ( {λ}_{Ex , x} )}{{q}_{p} ( {λ}_{Ex , x} ) {f}_{x} ( {λ}_{Ex , x} )}}{\frac{{F}_{Ref} ( {λ}_{Ex , Ref} )}{{q}_{p} ( {λ}_{Ex , Ref} ) {f}_{Ref} ( {λ}_{Ex , Ref} )}} \frac{{n}_{x}^{2}}{{n}_{Ref}^{2}} \qquad Equation 13$$

where the subscript “x” and “Ref” denote the sample and reference, respectively, F(λ_{Ex}) is the integrated fluorescence photon flux with excitation at λ_{Ex}, q_{P}(λ_{Ex}) is the excitation photon flux at λ_{Ex}, f(λ_{Ex}) is the absorption factor at λ_{Ex}, and n is the refractive index of the solvent. Therefore eq. 6 indicates that N_{Em} and N_{Abs} are proportional to F(λ_{Ex}) (total amount of emitted photon flux) and q_{P}(λ_{Ex})×f(λ_{Ex}) (total amount of excited photons), respectively, and the refractive index difference needs to be considered when comparing two different fluorophores. F(λ_{Ex}) is the fluorescence photon flux generated by exciting the fluorophore at λ_{Ex} and measured at λ_{Em} (q_{P},λ_{Ex}^{f}(λ_{Em})) integrated over the entire emission spectrum (λₐCλ_{Em} Cλ_{b}) as in eq. 7,

$$F ( {λ}_{Ex} ) = {\int }_{{λ}_{a}}^{{λ}_{b}} {q}_{p , {λ}_{Ex}}^{f} ( {λ}_{Em} ) d {λ}_{Em} = {\int }_{{λ}_{a}}^{{λ}_{b}} \frac{{I}_{{λ}_{Ex}} ( {λ}_{Em} )}{s ( {λ}_{Em} )} \frac{{λ}_{Em}}{hc} d {λ}_{Em} \qquad Equation 14$$

q_{P},λ_{Ex}^{f}(λ_{Em}) is the emission intensity measured at λ_{Em} (I)_{λEx} (λ_{Em})) corrected by the wavelength-dependent responsivity of the detector (s(λ_{Em})). Since the QY is the ratio between the number of photons, I(λ_{Em}) should be presented as a photonic quantity (e.g., photon counts per second (cps)). If I(λ_{Em}) is measured as a radiometric quantity (e.g. W/s), it should be converted to a photonic quantity by dividing with

$$\frac{hc}{{λ}_{Em}} ( h \text{:} Plank constant ; c \text{:} speed of light ) ,$$

the energy of a photon with wavelength λ_{Em}.
f(λ_{Ex}) is defined as the fraction of excitation photons absorbed by the sample at λ_{Ex} which can be formulated in terms of transmittance (T(λ_{Ex})) or absorbance (A(λ_{Ex})) using Equation 15,

f(λ_{Ex})=1−T(λ_{Ex})=1−10^{-A(λ}^{_{Ex}}⁾ Equation 15

q_{P}(λ_{Ex}) is excitation source intensity at λ_{Ex} measured by photodetector are corrected by the wavelength-dependent sensitivity of the detector as in the emission photon flux calculation. Also it must be read as or converted to a proper photonic quantity that is linearly proportional to the number of excitation photons.

### Excitation Wavelength-Dependent Quantum Yield Calculation Using the Photoluminescence Excitation Spectrum

Photoluminescence excitation (PLE) spectra provide the change in the fluorescence intensity at a specific emission wavelength (λ_{Em Max}) depending on the excitation wavelength, or a plot of q_{P,λEx}^{f}(λ_{Em}*) versus λ_{Ex}. If the shapes (e.g. λ_{Em Max}, FWHM) of the fluorescence spectra obtained at different excitation wavelengths are identical, the integrated fluorescence photon flux F(λ_{Ex}) can simply be derived from the PLE spectrum and one F(λ_{Ex}) measured at a reference excitation wavelength according to Equation 16,

$$F ( {λ}_{Ex} ) = \frac{{q}_{p , {λ}_{Ex}}^{f} ( {λ}_{Em}^{*} )}{{q}_{p , {λ}_{Ex Ref}}^{f} ( {λ}_{Em}^{*} )} F ( {λ}_{Ex Ref} ) \qquad Equation 16$$

### Absorption Factor (f) Vs Absorbance (A) in Quantum Yield Calculation

For very dilute samples (A<0.1), the absorption factor f(λ_{Ex}) is often replaced by absorbance A(λ_{Ex}) by using a power series expansion as shown in Equations 17 and 18

$$\begin{matrix} {10}^{- A} = {\sum }_{n = 0}^{∞} \frac{1}{n !} \frac{{d}^{n}}{d {A}^{n}} ( {10}^{- A} ) = {\sum }_{n = 0}^{∞} \frac{{( - ln 10 )}^{n}}{n !} {A}^{n} & Equation 17 \\ f ( {λ}_{Ex} ) = 1 - {10}^{- A ( {λ}_{Ex} )} = 1 - ( 1 - 2.3026 A ( {λ}_{Ex} ) + \frac{{2.3026}^{2}}{2} {A}^{2} ( {λ}_{Ex} ) - … ) \approx 2.3026 A ( {λ}_{Ex} ) & Equation 18\end{matrix}$$

The constant 2.3026 is dropped off when calculating the ratio between absorbance of a reference and a sample for QY calculation. However, this approximation is accurate only when the absorbance values of both the reference (A_{Ref}) and sample (Aₓ) are very low and close to each other. FIG. 7A shows the difference between the QY calculated by using the ratio of Aₓ/A_{Ref} and that calculated by using fₓ/f_{Ref}. Notice that there can be up to 10% error in QY from absorbances even when both A_{Ref} and Aₓ are lower than 0.1 but the values are different (e.g. A_{Ref}=0.01 and Aₓ=0.1). Moreover, such deviation quickly becomes enormous when the absorbance of a sample further increases relative to the absorbance of the reference. In fact, this is generally the case for calculating an excitation wavelength-dependent QY of a QD sample from its PLE spectrum. Although for a dilute QD solution with an absorbance <0.1 near the bandedge, the solution can still show very high absorbance as the wavelengths gets shorter due to the band-type electronic structure of a QD as shown in FIG. 7B. Hence, it is unavoidable that the sample is excited at regions where the sample absorbance is much higher than the reference absorbance when collecting a PLE spectrum, and there can be a significant error when absorbance is used instead of absorption factor in the QY calculation.

### Measurement of Excitation Wavelength-Dependent Quantum Yield of Quantum Dots Sample Preparation:

A fluorescein solution in 1 mM NaOH water (φ_{f,Ref}=0.92; n=1.333) was used as the QY reference. See (66) Grabolle et al. and (67) Wurth et al. The fluorescein absorbance at the lowest energy absorption peak (490 nm) was adjusted to 0.03-0.05. QD sample solutions were prepared in either chloroform (organic soluble QDs; n=1.445) or 10 mM NaOH water (amphipol-coated water-soluble QDs; n=1.333). QD solutions were centrifuged to remove any QD aggregates or undissolved debris that may induce scattering. Then the solutions were diluted to make the absorbance at 490 nm 0.03-0.05.

### Relative Quantum Yield Measurement:

The absorption spectrum of a sample or the reference was first obtained by absorption spectrophotometry. The spectrum was then converted to an absorption factor spectrum for the QY calculation. The emission spectrum was obtained by exciting the sample either at 490 nm (λ_{Ex} of fluorescein) or 400 nm. Data acquisition conditions such as excitation and emission slit width, emission acquisition time, and number of scans were adjusted to obtain the signals with the highest signal-to-noise ratio within the dynamic range of the detectors. Then the condition was kept the same for all samples and the references. The emission intensity was recorded in cps units (photonic scale). The spectrum was corrected by the blank spectrum of solvent then multiplied by the wavelength-dependent sensitivity correction factor for the detector acquired from the manufacturer to represent the emission photon flux. Then, this corrected emission spectrum was integrated over the entire emission wavelength range to calculate the total fluorescence photon flux (αN_{Em}). The photon flux of the excitation source was monitored simultaneously by a silicon photodiode built in the sample compartment of the fluorometer. The diode reads the relative photo flux in microAmp units (a photonic scale) and it was also corrected by its wavelength-dependent sensitivity given by the manufacturer. Then, excitation photon flux was multiplied by the absorption factor at the same wavelength (a Nabs), and used to normalize the total fluorescence photon flux (αN_{Em})/N_{Em}). Finally, QY was determined by calculating the ratio between this normalized quantity of a sample against that of the fluorescein reference. A PLE spectrum was obtained by monitoring the emission signal at the peak maximum and sweeping the excitation wavelength (typically from ˜350 nm up to 20-40 nm shorter than the peak maximum). Both emission and excitation photon fluxes were corrected by the detector sensitivities and the PLE curve was obtained by plotting the emission photon flux divided by the excitation photon flux against the excitation wavelength. Excitation wavelength-dependent QY was then calculated by dividing the PLE spectra with the absorption factor spectra.

### Example 7

### Single Particle Brightness Measurements

Polymer-coated QDs dispersed in phosphate buffered saline were spin-coated on glass coverslips and imaged via epifluorescence microscopy to acquire single-particle fluorescence movies. The movies were analyzed using algorithms based on previous reports that are described in further detail in this Example. See (29) Arnspang et al.

QD Sample preparation.

Amphipol-coated QDs dissolved in 10 mM sodium hydroxide buffer were transferred to 1×PBS solution at a concentration of 1 μM and allowed to incubate at room temperature for 30 minutes. Afterward, the QDs were centrifuged at 7000 g for 10 minutes in order to remove any aggregated particles. For imaging, QDs were nonspecifically adhered to #1.5 glass coverslips by spin-coating femtomolar dilutions at 2500 rpm for 30 seconds. Prior to spin-coating, the coverslips were rinsed with ethanol, methanol, and acetone in order to remove any organic residue.

Image Analysis.

Epifluorescence videos of single particles were saved as TIFF stacks and imported into Matlab for analysis using custom codes based on previous reports on single fluorophore analysis. See (68) Jaqaman et al., (69) Serge et al., and (29) Arnspang et al. First, (i,j) coordinates of fluorescent spots were obtained from integrated images of all frames of each stack by calling the detection/estimation/deflation algorithm of Serge et al.¹⁶ See (69) Serge et al. Using these positions, the fluorescence intensities of the detected QDs for each frame were measured by slight modifications to the methods of Arnspang et al., using the average value of a 3×3 pixel array centered on the detected position. See (29) Arnspang et al. Histograms of intensity value per frame (frequency vs. intensity) were then constructed for each detected QD, and the histograms were fit to a sum of two functions, a Gaussian background (f₁(x)) and an assymetric Gaussian signal (f₂(x)). See Equations 19-21.

$$\begin{matrix} f ( x ) = {f}_{1} ( x ) + {f}_{2} ( x ) & Equation 19 \\ {f}_{1} ( x ) = \frac{{α}_{1}}{{σ}_{1} \sqrt{2 π}} exp [ - \frac{1}{2} {( \frac{x - {x}_{1}}{{σ}_{1}} )}^{2} ] & Equation 20 \\ {f}_{2} ( x ) = \frac{1}{r + 1} \frac{{α}_{2}}{{σ}_{2} \sqrt{2 π}} erfc ( - \frac{x - {x}_{1}}{{σ}_{1} \sqrt{π}} ) \times \{ \begin{matrix}exp [ - \frac{1}{2 r} {( \frac{x - {x}_{2}}{{σ}_{2}} )}^{2} ] , & for x < {x}_{2} \\ exp [ - \frac{1}{2} {( \frac{x - {x}_{2}}{{σ}_{2}} )}^{2} ] , & for x \geq {x}_{2}\end{matrix} & Equation 21\end{matrix}$$

Here α, x, and σ are the integrated area, the centroid position in intensity, and the width of the Gaussian function, respectively. The subscript “1” corresponds to the QD state when it is entirely “off” (the noise level), and the subscript “2” corresponds to the QD state when it is “on.” The asymmetry factor r, for which 0<r≦1, signifies that a single isolated QD has a maximum intensity value of fluorescence which can be fit as a Gaussian, however random blinking events yield lower intensity intermediate states that skew the distribution toward the low-intensity side of the function.

The function was fit to the data using the least squares method, yielding the following parameters for each detected particle: α₁, x₁, σ₁, α₂, x₂, σ₂, and r, as well as relative variances for each parameter (e.g. RV(α₁). The important parameters to extract, as displayed in FIG. 5 of the main text are x₁ and x₂, the noise and signal intensities per particle, plotted as a histogram across the QD population. At this point of analysis, all spots had been detection without preference, and as such many comprised particles with overlapping point spread functions. To maximize the likelihood of only detecting individual QDs, we imposed the following criteria to the data obtained for all particles detected, chosen to select particles exhibiting conventional single-molecule behavior. (1) QDs “on” for at least 20% of frames, or α₂/(α₁+α₂)≧0.20, (2) “on” for no more than 92% of frames, or α₂/(α₁+α₂)≦0.92 so that a distinct “off” level could be determined, (3) noise signal width less than 3.6, or σ₁<3.6, to avoid poor noise level fits, which were common for large particle aggregates (average σ in non-QD regions was 1.46±0.40 in our measurements), (4) relative variance for all fitting parameters less than 300%. Typically 40% of detected QD points were rejected based on these criteria, and importantly, all of these criteria were based on goodness of fit to the mathematical model and confidence of detecting the correct fit parameters, and not based on the absolute intensity values, so that our detected brightness values were not skewed. Histograms of the values of x₁ and x₂ are depicted in FIG. 5, after correcting the signal levels by the wavelength-specific sensitivity of the CCD camera.

### Example 8

### Intravital Microscopy

All procedures involving animals were conducted in accordance with the National Institutes of Health regulations and approved by the Albert Einstein College of Medicine animal use committee. Tumor tissue from female FVB mice transgenically expressing Polyoma middle T antigen (PyMT) under direction of the mouse mammary tumor virus (MMTV) promoter was cut into pieces of 2-3 mm and coated in matrigel. One piece of tumor was surgically implanted in the right lower mammary fat pad of a non-transgenic FVB mouse and allowed to grow to approximately 1 cm in diameter over 4-6 weeks. Intravital imaging of each tumor-bearing mouse was performed using a custom-built multiphoton microscope Olympus IX-71 with 20×0.95 numerical aperture water immersion objective with tunable femtosecond Mai-Tai laser tuned to 780 nm. Fluorescence and second-harmonic signals were separated via dichroic mirrors and collected using separate photomultiplier tubes. Further details on the animal model, microscopy technique, and image analysis are provided in this Example as follows.

Animals.

All procedures were conducted in accordance with the National Institutes of Health regulations and approved by the Albert Einstein College of Medicine animal use committee. PyMT tumor tissue from MMTV-PyMT (FVB mice) was cut into pieces of 2 to 3 mm and coated in matrigel (BD Biosciences, Franklin Lakes, N.J., USA). One piece of tumor was surgically implanted in the right lower mammary fat pads of FVB mice. After 4-6 weeks, when tumors are approximately 1 cm in diameter, live images of the tumor microenvironment were obtained using the skin flap procedure. See (70) Wyckoff et al.

In Vivo Multiphoton Microscopy.

Intravital imaging of PyMT tumor-bearing mice was performed using methods similar to those previously described. See (70) Wyckoff et al. Images were acquired on a custom-built multiphoton microscope Olympus IX-71 with a 20×0.95 NA water immersion objective and a tunable femtosecond laser (Mai Tai, Newport/Spectra-Physics) tuned to 780 nm for optimal excitation of QDs. See (32) Entenberg et al. The fluorescence and second-harmonic signals generated were collected via a dichroic mirror and sent to three photomultiplier-tube (PMT) detectors to allow detection of second harmonic generation (SHG), CFP (from tumor cells) and QDs in green and red. Images were acquired from 3 random 512×512 pixels at a depth of 50 μm (21 slices at steps of 2 μm).

Image analysis.

As previously described, image channels were balanced and subtracted to isolate the CFP signal. See (70) Wyckoff et al. An average intensity Z-projection was made for all channels. The average intensity projection is used for QD fluorescence to quantitatively determine the mean within a volume of interest. Five ROI were measured for each animal. The average pixel intensity of each ROI in the green channel was normalized to the average pixel intensity of the same ROI in the red channel. A single optical plane is presented in FIG. 6 in the main text.

### REFERENCES

The following references are with respect to the reference numbers, where cited, in the present patent application, and are also incorporated by reference herein in their entirety.
(1) Kovalenko, M. V. et al. Prospects of Nanoscience with Nanocrystals. ACS Nano 9, 1012-1057, (2015).
(2) Kairdolf, B. A. et al. Semiconductor Quantum Dots for Bioimaging and Biodiagnostic Applications. Ann. Rev. Anal. Chem. 6, 143-162, (2013).
(3) Anikeeva, P. O., Halpert, J. E., Bawendi, M. G. & Bulovic, V. Quantum dot light-emitting devices with electroluminescence tunable over the entire visible spectrum. Nano Lett. 9, 2532-2536, (2009).
(4) Salter, C. L. et al. An entangled-light-emitting diode. Nature 465, 594-597, (2010).
(5) Talapin, D. V., Lee, J. S., Kovalenko, M. V. & Shevchenko, E. V. Prospects of Colloidal Nanocrystals for Electronic and Optoelectronic Applications. Chem. Rev. 110, 389-458, (2010).
(6) Lee, Y. L. & Lo, Y. S. Highly Efficient Quantum-Dot-Sensitized Solar Cell Based on Co-Sensitization of CdS/CdSe. Adv. Funct. Mater. 19, 604-609, (2009).
(7) Konstantatos, G. & Sargent, E. H. Nanostructured materials for photon detection. Nat. Nanotech. 5, 391-400, (2010).
(8) Nozik, A. J. et al. Semiconductor Quantum Dots and Quantum Dot Arrays and Applications of Multiple Exciton Generation to Third-Generation Photovoltaic Solar Cells. Chem. Rev. 110, 6873-6890, (2010).
(9) Ladd, T. D. et al. Quantum computers. Nature 464, 45-53, (2010).
(10) Garcia-Santamaria, F. et al. Suppressed Auger Recombination in “Giant” Nanocrystals Boosts Optical Gain Performance. Nano Lett. 9, 3482-3488, (2009).
(11) Tisdale, W. A. et al. Hot-Electron Transfer from Semiconductor Nanocrystals. Science 328, 1543-1547, (2010).
(12) Vu, T. Q., Lam, W. Y., Hatch, E. W. & Lidke, D. S. Quantum dots for quantitative imaging: from single molecules to tissue. Cell Tissue Res. 360, 71-86, (2015).
(13) Cutler, P. J. et al. Multi-color quantum dot tracking using a high-speed hyperspectral line-scanning microscope. PLoS ONE 8, e64320, (2013).
(14) Kobayashi, H. et al. Simultaneous multicolor imaging of five different lymphatic basins using quantum dots. Nano Lett. 7, 1711-1716, (2007).
(15) Zrazhevskiy, P. & Gao, X. H. Quantum dot imaging platform for single-cell molecular profiling. Nat. Comm. 4, 1619, (2013).
(16) Ekimov, A. I. & Onushchenko, A. A. Quantum size effect in the optical-spectra of semiconductor micro-crystals. Soy. Phys. Semiconduct. 16, 775-778, (1982).
(17) Brus, L. E. A Simple-Model for the Ionization-Potential, Electron-Affinity, and Aqueous Redox Potentials of Small Semiconductor Crystallites. J. Chem. Phys. 79, 5566-5571, (1983).
(18) Smith, A. M. & Nie, S. M. Semiconductor nanocrystals: structure, properties, and bandgap engineering. Acc. Chem. Res. 43, 190-200, (2010).
(19) Yu, H., Li, J. B., Loomis, R. A., Wang, L. W. & Buhro, W. E. Two-versus three-dimensional quantum confinement in indium phosphide wires and dots. Nat. Mater. 2, 517-520, (2003).
(20) Murray, C. B., Norris, D. J. & Bawendi, M. G. Synthesis and characterization of nearly monodisperse CdE (E=S, Se, Te) semiconductor nanocrystallites. J. Am. Chem. Soc. 115, 8706-8715, (1993).
(21) Xie, R. G. & Peng, X. G. Synthetic scheme for high-quality InAs nanocrystals based on self-focusing and one-pot synthesis of InAs-based core-shell nanocrystals. Angew. Chem. Int. Ed. 47, 7677-7680, (2008).
(22) Murray, C. B. et al. Colloidal synthesis of nanocrystals and nanocrystal superlattices. IBM J. Res. Dev. 45, 47-56, (2001).
(23) Yu, M. W. & Peng, X. G. Formation of high-quality CdS and other II-VI semiconductor nanocrystals in noncoordinating solvents: Tunable reactivity of monomers. Angew. Chem. Int. Ed. 41, 2368-2371, (2002).
(24) McBride, J., Treadway, J., Feldman, L. C., Pennycook, S. J. & Rosenthal, S. J. Structural basis for near unity quantum yield core/shell nanostructures. Nano Lett. 6, 1496-1501, (2006).
(25) Keuleyan, S., Lhuillier, E. & Guyot-Sionnest, P. Synthesis of colloidal HgTe quantum dots for narrow mid-IR emission and detection. J. Am. Chem. Soc. 133, 16422-16424, (2011).
(26) Leatherdale, C., Woo, W., Mikulec, F. & Bawendi, M. On the absorption cross section of CdSe nanocrystal quantum dots. J. Phys. Chem. B 106, 7619-7622, (2002).
(27) Smith, A. M., Lane, L. A. & Nie, S. M. Mapping the spatial distribution of charge carriers in quantum-confined heterostructures. Nat. Comm. 5, 4506, (2014).
(28) Wurth, C., Grabolle, M., Pauli, J., Spieles, M. & Resch-Genger, U. Relative and absolute determination of fluorescence quantum yields of transparent samples. Nat. Protoc. 8, 1535-1550, (2013).
(29) Arnspang, E. C., Brewer, J. R. & Lagerholm, B. C. Multi-Color Single Particle Tracking with Quantum Dots. PLoS ONE 7, e48521, (2012).
(30) Pu, S. C. et al. The empirical correlation between size and two-photon absorption cross section of CdSe and CdTe quantum dots. Small 2, 1308-1313, (2006).
(31) Wyckoff, J., Gligorijevic, B., Entenberg, D., Segall, J. E. & Condeelis, J. High-resolution multiphoton imaging of tumors in vivo. Cold Spring Harb. Protoc. 2011, 1167-1184, (2011).
(32) Entenberg, D. et al. Setup and use of a two-laser multiphoton microscope for multichannel intravital fluorescence imaging. Nat. Protoc. 6, 1500-1520, (2011).
(33) Larson, D. R. et al. Water-soluble quantum dots for multiphoton fluorescence imaging in vivo. Science 300, 1434-1436, (2003).
(34) Gao, X. H. et al. In vivo molecular and cellular imaging with quantum dots. Curr. Opin. Biotechnol. 16, 63-72, (2005).
(35) Zhou, J. et al. Surface antigen profiling of colorectal cancer using antibody microarrays with fluorescence multiplexing. J. Immunol. Methods 355, 40-51, (2010).
(36) Klimov, V. I. Optical nonlinearities and ultrafast carrier dynamics in semiconductor nanocrystals. J. Phys. Chem. B 104, 6112-6123, (2000).
(37) Jasieniak, J. J., Smith, L., van Embden, J., Mulvaney, P. & Califano, M. Re-examination of the size-dependent absorption properties of CdSe quantum dots. J. Phys. Chem. C 113, 19468-19474, (2009).
(38) Peng, X. G., Schlamp, M. C., Kadavanich, A. V. & Alivisatos, A. P. Epitaxial growth of highly luminescent CdSe/CdS core/shell nanocrystals with photostability and electronic accessibility. J. Am. Chem. Soc. 119, 7019-7029, (1997).
(39) Susumu, K. et al. Enhancing the stability and biological functionalities of quantum dots via compact multifunctional ligands. J. Am. Chem. Soc. 129, 13987-13996, (2007).
(40) Smith, A. M. & Nie, S. M. Next-generation quantum dots. Nat. Biotechnol. 27, 732-733, (2009).
(41) Muro, E. et al. Small and stable sulfobetaine zwiterionic quantum dots for functional live-cell imaging. J. Am. Chem. Soc. 132, 4556-4557, (2010).
(42) Xu, J. M., Ruchala, P., Ebenstain, Y., Li, J. J. & Weiss, S. Stable, Compact, Bright Biofunctional Quantum Dots with Improved Peptide Coating. J. Phys. Chem. B 116, 11370-11378, (2012).
(43) Chen, O. et al. Compact high-quality CdSe—CdS core-shell nanocrystals with narrow emission linewidths and suppressed blinking. Nat. Mater. 12, 445-451, (2013).
(44) Dabbousi, B. O. et al. (CdSe)ZnS core-shell quantum dots: Synthesis and characterization of a size series of highly luminescent nanocrystallites. J. Phys. Chem. B 101, 9463-9475, (1997).
(45) Hines, M. A. & Guyot-Sionnest, P. Synthesis and characterization of strongly luminescing ZnS-capped CdSe nanocrystals. J. Phys. Chem. 100, 468-471, (1996).
(46) Chen, Y. F. et al. “Giant” multishell CdSe nanocrystal quantum dots with suppressed blinking. J. Am. Chem. Soc. 130, 5026-5027, (2008).
(47) Talapin, D. V. et al. Highly emissive colloidal CdSe/CdS heterostructures of mixed dimensionality. Nano Lett. 3, 1677-1681, (2003).
(48) Chen, O. et al. Synthesis of metal-selenide nanocrystals using selenium dioxide as the selenium precursor. Angew. Chem., Int. Ed. 47, 8638-8641, (2008).
(49) Greytak, A. B. et al. Alternating layer addition approach to CdSe/CdS core/shell quantum dots with near-unity quantum yield and high on-time fractions. Chem. Sci. 3, 2028-2034, (2012).
(50) Shea-Rohwer, L. E., Martin, J. E., Cal, X. & Kelley, D. F. Red-emitting quantum dots for solid-state lighting. ECS J. Solid State Sci. Technol. 2, R3112-R3118, (2013).
(51) Liu, W. et al. Compact biocompatible quantum dots via RAFT-mediated synthesis of imidazole-based random copolymer ligand. J. Am. Chem. Soc. 132, 472-483, (2010).
(52) Smith, A. M. & Nie, S. M. Minimizing the hydrodynamic size of quantum dots with multifunctional multidentate polymer ligands. J. Am. Chem. Soc. 130, 11278-11279, (2008).
(53) Palui, G., Na, H. B. & Mattoussi, H. Poly(ethylene glycol)-based multidentate oligomers for biocompatible semiconductor and gold nanocrystals. Langmuir 28, 2761-2772, (2012).
(54) Hoy, J. et al. Excitation energy dependence of the photoluminescence quantum yields of core and core/shell quantum dots. Phys. Chem. Lett. 4, 2053-2060 (2013).
(55) Chen, O. et al. Synthesis of metal-selenide nanocrystals using selenium dioxide as the selenium precursor. Angew. Chem. Int. Ed. 43, 8638-8641 (2008).
(56) Cao, Y. C. & Wang, J. One-pot synthesis of high-quality zinc-blende CdS nanocrystals. J. Am. Chem. Soc. 126, 14336-14337 (2004).
(57) Smith, A. M. & Nie, S. Bright and compact alloyed quantum dots with broadly tunable near-infrared absorption and fluorescence spectra through mercury cation exchange. J. Am. Chem. Soc. 133, 24-26 (2011).
(58) Gohon, Y. et al. Partial specific volume and solvent interactions of amphipol A8-35. Anal. Biochem. 334, 318-334 (2004).
(59) Carbone, L. et al. Synthesis and micrometer-scale assembly of colloidal CdSe/CdS nanorods prepared by a seeded growth approach. Nano Lett. 7, 2941-2950 (2007).
(60) Smith, A. M. & Nie, S. Compact quantum dots for single-molecule imaging in live cells. J. Vis. Exp. e4236 (2012).
(61) Liu, W. et al. Compact biocompatible quantum dots via RAFT-mediated synthesis of imidazole-based random copolymer ligand. J. Am. Chem. Soc. 132, 472-483 (2010).
(62) Park, J. et al. Compact and Stable Quantum Dots with Positive, Negative, or Zwitterionic Surface: Specific Cell Interactions and Non-Specific Adsorptions by the Surface Charges. Adv. Funct. Mater. 21, 1558-1566 (2011).
(63) Greytak, A. B. et al. Alternating layer addition approach to CdSe/CdS core/shell quantum dots with near-unity quantum yield and high on-time fractions. Chem. Sci. 3, 2028-2034 (2012).
(64) Jasieniak, J., Smith, L., van Embden, J., Mulvaney, P. & Califano, M. Re-examination of the size-dependent absorption properties of CdSe quantum dots. J. Phys. Chem. C 113, 19468-19474 (2009).
(65) Demas, J. N. & Crosby, G. A. The measurement of photoluminescence quantum yields. A review. J. Phys. Chem. 75, 991-1024 (1971).
(66) Grabolle, M. et al. Determination of the fluorescence quantum yield of quantum dots: suitable procedures and achievable uncertainties. Anal. Chem. 81, 6285-6294 (2009).
(67) Wurth, C., Grabolle, M., Pauli, J., Spieles, M. & Resch-Genger, U. Relative and absolute determination of fluorescence quantum yields of transparent samples. Nat. Protoc. 8, 1535-1550 (2013).
(68) Jaqaman, K. et al. Robust single-particle tracking in live-cell time-lapse sequences. Nat. Methods. 5, 695-702 (2008).
(69) Serge, A., Bertaux, N., Rigneault, H. & Marguet, D. Dynamic multiple-target tracing to probe spatiotemporal cartography of cell membranes. Nat. Methods 5, 687-694 (2008).
(70) Wyckoff, J., Gligorijevic, B., Entenberg, D., Segall, J. & Condeelis, J. High-Resolution Multiphoton Imaging of Tumors In Vivo. Cold Spring Harb. Protoc. 2011, 1167-1184 (2011).

### INCORPORATION BY REFERENCE

The entire disclosure of each of the patent documents, including certificates of correction, patent application documents, scientific articles, governmental reports, websites, and other references referred to herein is incorporated by reference herein in its entirety for all purposes. In case of a conflict in terminology, the present specification controls.

### EQUIVALENTS

The invention can be embodied in other specific forms without departing from the spirit or essential characteristics thereof. The foregoing embodiments are to be considered in all respects illustrative rather than limiting on the invention described herein. In the various embodiments of the methods and systems of the present invention, where the term comprises is used with respect to the recited steps or components, it is also contemplated that the methods and systems consist essentially of, or consist of, the recited steps or components. Further, it should be understood that the order of steps or order for performing certain actions is immaterial so long as the invention remains operable. Moreover, two or more steps or actions can be conducted simultaneously.

In the specification, the singular forms also include the plural forms, unless the context clearly dictates otherwise. Unless defined otherwise, all technical and scientific terms used herein have the same meaning as commonly understood by one of ordinary skill in the art to which this invention belongs. In the case of conflict, the present specification will control.

Furthermore, it should be recognized that in certain instances a composition can be described as being composed of the components prior to mixing, because upon mixing certain components can further react or be transformed into additional materials.

All percentages and ratios used herein, unless otherwise indicated, are by weight.

What is claimed is:

1. An array of two or more semiconductor nanocrystals in which the fluorescence brightness is matched to a predefined brightness, the nanocrystals comprising:
(a) an alloy core selected from a ternary or higher order alloy core that controls emission color by the selection of the composition of the core or a binary alloy core that controls emission color by the selection of the core diameter, said emissions for said at least two or more nanocrystals being of at least two different emission wavelengths;
(b) a first epitaxially deposited concentric shell of controlled thickness, deposited on the alloy core, that modulates the extinction coefficient of the emission of the alloy core to match the extinction coefficients of the alloy cores across the array of nanocrystals; and
(c) a second epitaxially deposited concentric shell of controlled thickness, deposited on the first concentric shell to match the quantum yield of the emission of the alloy cores across the array of nanocrystals.

2. An array according to claim 1, wherein the fluorescence brightness is matched across a range of emission colors and excitation wavelengths

3. The nanocrystal of claim 1, wherein the alloy core is a ternary or higher order alloy core that controls emission color by the selection of the composition of the core.

4. The nanocrystal of claim 3, wherein the ternary or higher order alloy core comprises an alloy selected from a mixture of at least three of the following elements: cadmium, mercury, selenium, sulfur, tellurium, and zinc.

5. The nanocrystal of claim 1, wherein the alloy core is a ternary alloy core that controls emission color by the selection of the composition of the core.

6. The nanocrystal of claim 5, wherein the ternary alloy core comprises a mixture of (a) a mixture of cadmium, selenium, and sulfur or (b) a mixture of mercury, selenium, and sulfur.

7. The nanocrystal of claim 1, wherein the alloy core is a binary alloy core that controls emission color by the selection of the core diameter.

8. The nanocrystal of claim 1, wherein the higher order alloy core is a quaternary alloy core that controls emission color by the selection of the composition of the core.

9. The nanocrystal of claim 1, wherein the alloy core comprises Hg(x)Cd(1-x)Se(y)S(1-y) wherein x and y are independently selected from any real number between zero and 1, inclusive.

10. The nanocrystal of claim 1, wherein the alloy core comprises Cd(x)Zn(1-x)Se(y)S(1-y) wherein x and y are independently selected from any real number between zero and 1, inclusive.

11. The nanocrystal of claim 1, wherein the first shell comprises CdS.

12. The nanocrystal of claim 1, wherein the second shell comprises ZnS.

13. The nanocrystal of claim 1 having a diameter from about 2 nm to about 100 nm.

14. The nanocrystal of claim 1, wherein the alloy core has a diameter from about 2 nm to about 20 nm.

15. The nanocrystal of claim 1, wherein the first shell has a thickness from about 0.1 nm to about 10 nm.

16. The nanocrystal of claim 1, wherein the second shell has a thickness from about 0.1 nm to about 10 nm.

17. A biomedical imaging device comprising an array of 2 or more nanocrystals according to claim 1.

18. A fluorescent lighting device comprising an array of 2 or more nanocrystals according to claim 1.

19. A biological or biomedical fluorescent probe comprising an array of 2 or more nanocrystals according to claim 1.

20. A solar panel comprising an array of 2 or more nanocrystals according to claim 1.

21. An optoelectronic device comprising an array of 2 or more nanocrystals according to claim 1.

22. A computational device comprising an array of 2 or more nanocrystals according to claim 1.

23. A method for making a semiconductor nanocrystal in which one or more of the following properties of the nanocrystal is matched to a predefined value: (i) extinction coefficient, (ii) absorption cross section, (iii) fluorescence quantum yield, or (iv) fluorescence brightness; comprising:
(a) preparing an alloy core selected from a ternary or higher order alloy core that controls emission color by the selection of the composition of the core or a binary alloy core that controls emission color by the selection of the core diameter;
(b) epitaxially depositing a first concentric shell of controlled thickness on the alloy core, that modulates the extinction coefficient of the emission of the alloy core to match the extinction coefficient to a predefined value; and
(c) epitaxially depositing a second concentric shell of controlled thickness on the first concentric shell to match the quantum yield of the emission of the alloy core to a predefined value;
wherein the resulting nanocrystal exhibits one or more properties of the predefined value.

24. A method for equalizing the fluorescence brightness of an array of two or more semiconductor nanocrystals to a predefined brightness, comprising:
(I) selecting one or more semiconductor nanocrystals of a first nanocrystal composition, comprising:
(a) an alloy core selected from a ternary or higher order alloy core that controls emission color by the selection of the composition of the core or a binary alloy core that controls emission color by the selection of the core diameter, said emission colors for said at least two or more nanocrystals being of at least two different emission wavelengths;
(b) a first epitaxially deposited concentric shell of controlled thickness, deposited on the alloy core, that modulates the extinction coefficient of the emission of the alloy core to match the extinction coefficients across the array of nanocrystals; and
(c) a second epitaxially deposited concentric shell of controlled thickness, deposited on the first concentric shell to match the quantum yield of the emission of the alloy core across the array of nanocrystals;
(II) selecting one or more semiconductor nanocrystals of a second nanocrystal composition, comprising:
(a) an alloy core selected from a ternary or higher order alloy core that controls emission color by the selection of the composition or a binary alloy core that controls emission color by the selection of the core diameter, said emission colors for said at least two or more nanocrystals being of at least two different emission wavelengths;
(b) a first epitaxially deposited concentric shell of controlled thickness, deposited on the alloy core, that modulates the extinction coefficient of the emission of the alloy core to match the extinction coefficients of the alloy core across the array of nanocrystals; and
(c) a second epitaxially deposited concentric shell of controlled thickness, deposited on the first concentric shell to match the quantum yield of the emission of the alloy core across the array of nanocrystals; and
(III) optionally selecting one or more semiconductor nanocrystals from one or more further nanocrystal compositions having a composition other than the first or second nanocrystal composition, comprising:
(a) an alloy core selected from a ternary or higher order alloy core that controls emission color by the selection of the composition or a binary alloy core that controls emission color by the selection of the core diameter, said emission colors for said at least two or more nanocrystals being of at least two different emission wavelengths;
(b) a first epitaxially deposited concentric shell of controlled thickness, deposited on the alloy core, that modulates the extinction coefficient of the emission of the alloy core to match the extinction coefficients across the array of nanocrystals; and
(c) a second epitaxially deposited concentric shell of controlled thickness, deposited on the first concentric shell to match the quantum yield of the emission of the alloy core across the array of nanocrystals;
wherein the composition of the first, second, and any optional further nanocrystal composition is modified such that the fluorescence brightness of the array is equalized to the predefined brightness.
